(19) United States
(12) Patent Application Publication
(10) Pub. No.: US 2023/0217693 A1
(43) Pub. Date: Jul. 6, 2023

(54) ENCAPSULATION LAYER HAVING LOW REFRACTIVE INDEX LAYER AND DISPLAY DEVICE HAVING THE SAME

(71) Applicant: Samsung Display Co., Ltd., Yongin-si (KR)

(72) Inventors: HYOJOON KIM, Seoul (KR); SEON-TAE YOON, Hwaseong-si (KR); EUNJUNG KIM, Suwon-si (KR); HYUN-SEOK KIM, Hwaseong-si (KR); Soonkyu CHA, Hwaseong-si (KR)

(21) Appl. No.: 18/075,514

(22) Filed: Dec. 6, 2022

(30) Foreign Application Priority Data
Jan. 3, 2022 (KR) 10-2022-0000175

(51) Int. Cl. H10K 50/858; H10K 59/35; H10K 50/844

(52) U.S. Cl. CPC H01L 51/5275; H01L 27/3211; H01L 51/5256; H01L 27/3244

(57) ABSTRACT

A display device includes a plurality of light emitting elements which provide source light, a plurality of light control parts which respectively correspond to the plurality of light emitting elements and have a refractive index, each of the plurality of light control parts receiving the source light and outputting a light having a color, and an encapsulation layer which is between the plurality of light emitting elements and the plurality of light control parts. The encapsulation layer includes in order from the plurality of light emitting elements to the plurality of light control parts, a first inorganic film and a low-refractive index organic film which contacts the first inorganic film and has a refractive index lower than the refractive index of the plurality of light control parts.

This application claims priority to Korean Patent Application No. 10-2022-0000175 filed on Jan. 03, 2022, and all the benefits accruing therefrom under 35 U.S.C. §119, the disclosures of which are incorporated by reference herein in their entireties.

### BACKGROUND

### Field

Embodiments of the present disclosure described herein relate to a display device, and more particularly, relate to a display device having improved light emission efficiency.

### Description of the Related Art

Multimedia devices, such as a television, a mobile phone, a tablet computer, a computer, a car navigation unit, a game machine, and the like, may include a display device for displaying an image. The display device may include a plurality of pixels for displaying the image. Each of the pixels may include a light emitting element that generates light and a drive element which is connected to the light emitting element.

To improve visibility and color purity, a display device includes a light control layer that controls the wavelength range of source light.

### SUMMARY

In a display device including a light control layer that controls the wavelength range of source light, light loss may occur in the process in which the source light passes through the light control layer and is emitted toward a display surface.

Embodiments of the present disclosure provide a display device having improved light emission efficiency and a reduced thickness.

According to an embodiment, a display device includes a plurality of light emitting elements which provide source light, each light emitting element including a first electrode, an emissive part, and a second electrode sequentially stacked one above another, an encapsulation layer on the plurality of light emitting elements, a barrier rib which is on the encapsulation layer and which defines a plurality of openings therein to correspond to the plurality of light emitting elements, respectively, and a plurality of light control parts, each of which receives the source light and outputs light having a predetermined color, the plurality of light control parts being in the plurality of openings, respectively. The encapsulation layer includes a first inorganic film which covers the second electrode of each of the plurality of light emitting elements and a low-refractive index organic film which makes contact with the first inorganic film. The low-refractive index organic film has a lower refractive index than the light control parts.

The low-refractive index organic film may have a refractive index of about 1.15 to about 1.35.

The low-refractive index organic film may have a thickness of about 1 micrometer (µm) to about 6 micrometers (µm).

The encapsulation layer may further include a second inorganic film between the low-refractive index organic film and the plurality of light control parts, and the low-refractive index organic film may have a lower refractive index than the second inorganic film.

The display device may further include a low-refractive index layer on the plurality of light control parts, and the low-refractive index layer may have a lower refractive index than the light control parts.

The low-refractive index layer may overlap the plurality of light control parts.

The low-refractive index layer may include a plurality of low-refractive index patterns corresponding to the plurality of light control parts, respectively, and spaced apart from each other.

The emissive part may include a plurality of emissive layers, and the plurality of emissive layers may emit light having the same color.

The emissive part may include a plurality of emissive layers, and the plurality of emissive layers may emit light having different colors.

The plurality of light emitting elements may include first to third light emitting elements corresponding to first to third pixel areas which emit light having different colors. The emissive parts of the first to third light emitting elements may have different thicknesses. The low-refractive index organic film may cover the first to third light emitting elements and may provide a flat upper surface.

The display device may further include a plurality of color filters on the plurality of light control parts, respectively.

According to an embodiment, a display device includes a light emitting element, a barrier rib which is on the light emitting element and defines a plurality of openings therein, a plurality of light control parts in the plurality of openings, respectively, and at least one of the light control parts including a quantum dot, a first low-refractive index film between the light emitting element and the plurality of light control parts, and a second low-refractive index film on the plurality of light control parts, and the first low-refractive index film includes an organic film and has a thickness of 6 micrometers (µm) or less.

The first low-refractive index film may have a refractive index of 1.15 to 1.35.

The display device may further include an inorganic film which is between the first low-refractive index film and the light emitting element and which makes contact with the first low-refractive index film.

The display device may further include an inorganic film which is between the first low-refractive index film and the plurality of light control parts and which makes contact with the first low-refractive index film.

The display device may further include a plurality of inorganic films which make contact with the first low-refractive index film, and the first low-refractive index film may be between the plurality of inorganic films.

The second low-refractive index film may cover all of the plurality of light control parts.

The second low-refractive index film may include a plurality of low-refractive index patterns corresponding to the plurality of light control parts, respectively, and spaced apart from each other.

According to an embodiment, a display device includes a plurality of light emitting elements, an encapsulation layer which seals the plurality of light emitting elements and includes a low-refractive index organic film, a barrier rib which is on the encapsulation layer and defines a plurality of openings therein to correspond to the plurality of light emitting elements, respectively, and a plurality of light control parts in the plurality of openings, respectively, at least one of the light control parts including a quantum dot, and the low-refractive index organic film has a refractive index of 1.35 or less.

The plurality of light emitting elements may include first to third light emitting elements corresponding to first to third pixel areas which emit light having different colors. The first to third light emitting elements may provide a stepped upper surface, and the low-refractive index organic film may cover the stepped upper surface and may provide a flat upper surface.

### BRIEF DESCRIPTION OF THE FIGURES

The above and other objects and features of the present disclosure will become apparent by describing in detail embodiments thereof with reference to the accompanying drawings.

FIG. 1 is a perspective view of a display device according to an embodiment of the present disclosure.

FIG. 2 is an exploded perspective view of the display device according to an embodiment of the present disclosure.

FIG. 3 is a plan view of a display panel according to an embodiment of the present disclosure.

FIG. 4 is an enlarged plan view of a display module according to an embodiment of the present disclosure.

FIG. 5 is a cross-sectional view of the display module according to an embodiment of the present disclosure.

FIGS. 6A to 6C are cross-sectional views of the display module according to embodiments of the present disclosure.

FIGS. 7A and 7B are cross-sectional views of the display module according to embodiments of the present disclosure.

FIG. 8 is a cross-sectional view of a light emitting element according to an embodiment of the present disclosure.

### DETAILED DESCRIPTION

Various changes can be made to the present disclosure, and various embodiments of the present disclosure may be implemented. Thus, embodiments are illustrated in the drawings and described as examples herein. However, it should be understood that the present disclosure is not to be construed as being limited thereto and covers all modifications, equivalents, and alternatives falling within the spirit and scope of the present disclosure.

In this specification, when it is mentioned that a component (or, an area, a layer, a part, etc.) is referred to as being related to another element such as being “on”, “connected to” or “coupled to” another component, this means that the component may be directly on, connected to, or coupled to the other component or a third component may be present therebetween. In contrast, when it is mentioned that a component (or, an area, a layer, a part, etc.) is referred to as being related to another element such as being “directly on”, “directly connected to” or “directly coupled to” another component, this means that a third component (e.g., intervening component) is not present therebetween.

Identical reference numerals refer to identical components. Additionally, in the drawings, the thicknesses, proportions, and dimensions of components are exaggerated for effective description.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes all of one or more combinations defined by related components.

Terms such as first, second, and the like may be used to describe various components, but the components should not be limited by the terms. The terms may be used only for distinguishing one component from other components. For example, without departing the scope of the present disclosure, a first component may be referred to as a second component, and similarly, the second component may also be referred to as the first component.

The terms of a singular form may include plural forms unless otherwise specified. As used herein, a reference number may indicate a singular element or a plurality of the element. For example, a reference number labeling a singular form of an element within the drawing figures may be used to reference a plurality of the singular element within the text of specification.

In addition, terms such as “below”, “under”, “above”, and “over” are used to describe a relationship of components illustrated in the drawings. The terms are relative concepts and are described based on directions illustrated in the drawing.

It should be understood that terms such as “comprise”, “include”, and “have”, when used herein, specify the presence of stated features, numbers, steps, operations, components, parts, or combinations thereof, but do not preclude the presence or addition of one or more other features, numbers, steps, operations, components, parts, or combinations thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ± 30%, 20%, 10% or 5% of the stated value.

Unless otherwise defined, all terms used herein, including technical or scientific terms, have the same meanings as those generally understood by those skilled in the art to which the present disclosure pertains. Such terms as those defined in a generally used dictionary are to be interpreted as having meanings equal to the contextual meanings in the relevant field of art, and are not to be interpreted as having ideal or excessively formal meanings unless clearly defined as having such in the present application.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, a display device DD according to an embodiment of the present disclosure will be described with reference to the accompanying drawings.

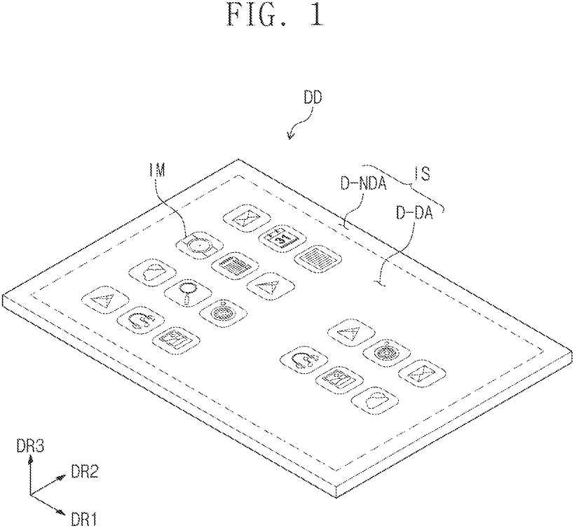

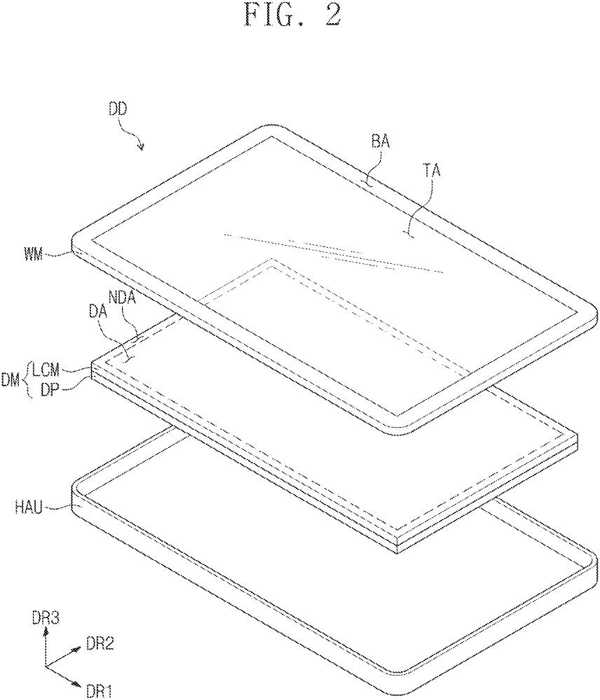

FIG. 1 is a perspective view of the display device DD according to an embodiment. FIG. 2 is an exploded perspective view of the display device DD according to the embodiment illustrated in FIG. 1.

The display device DD may be a device that is activated in response to an electrical signal and that displays an image. The display device DD may include various embodiments that provide an image to outside of the display device DD (e.g., to a user). For example, the display device DD may be a large display device such as a television, outdoor signage, or the like, or may be a small and medium-sized display device such as a monitor, a mobile phone, a tablet computer, a computer, a car navigation unit, a game machine, or the like. However, the embodiments of the display device DD are illustrative, and the display device DD is not limited to any one device as long as it does not deviate from the spirit and scope of the present disclosure.

Referring to FIG. 1, the display device DD may have a rectangular shape with long sides extending in (or along) a first direction DR1, and short sides extending in (or along) a second direction DR2, on a plane. The plane may be defined by the first direction DR1 and the second direction DR2 crossing each other. However, without being limited thereto, the display device DD may have various shapes such as a circular shape, a polygonal shape, and the like.

The display device DD may display an image IM in a third direction DR3 (e.g., a thickness direction) through a display surface IS parallel to a plane defined by the first direction DR1 and the second direction DR2. The third direction DR3 may be substantially parallel to the normal direction of the display surface IS. The display surface IS on which the image IM is displayed may correspond to the front surface of the display device DD. The image IM may include a still image as well as a dynamic image. In FIG. 1, icon images are illustrated as an example of the image IM.

In this embodiment, the front surface (or, the upper surface) and the rear surface (or, the lower surface) of each of members (or units) may be defined based on the direction in which the image IM is displayed. The front surface and the rear surface may be opposite each other in the third direction DR3, and the normal directions of the front surface and the rear surface may be parallel to the third direction DR3. The separation distance between the front surface and the rear surface defined in the third direction DR3 may correspond to the thickness of the member (or, the unit). A thickness direction of the display device DD and various components or layers thereof may be defined along the third direction DR3.

The expression “on a plane” used herein may mean that it is viewed in the third direction DR3. The expression “on a section” used herein may mean that it is viewed in the first direction DR1 and/or the second direction DR2. The directions indicated by the first to third directions DR1, DR2, and DR3 may be relative concepts and may be changed to different directions.

FIG. 1 illustrates the display device DD having the display surface IS which is flat (e.g., a flat display surface IS). However, the display surface IS of the display device DD is not limited thereto and may have a curved shape or a three-dimensional shape.

The display device DD may be a flexible display device. The term “flexible” used herein may refer to a property of being bendable, rollable, curvable, etc. so as to be bent, rolled, curved, etc., and may include everything from a structure that can be fully folded to a structure that can be bent to a level of several nanometers (nm). For example, the display device DD that is flexible may be a curved display device or a foldable display device. Without being limited thereto, the display device DD may be a rigid display device.

The display surface IS of the display device DD may include a display portion D-DA and a non-display portion D-NDA. The display portion D-DA may be a portion where the image IM is displayed on the front surface of the display device DD, and the image IM may be visually recognized through the display portion D-DA. Although the display portion D-DA having a rectangular shape on the plane is illustrated in this embodiment, the display portion D-DA may have various shapes depending on the design of the display device DD.

The non-display portion D-NDA may be a portion where the image IM is not displayed on the front surface of the display device DD. The non-display portion D-NDA may be a portion that has a predetermined color and blocks light. The non-display portion D-NDA may be adjacent to the display portion D-DA. For example, the non-display portion D-NDA may be disposed outside the display portion D-DA and may surround the display portion D-DA in a plan view (e.g., along the plane). However, this is illustrative, and the non-display portion D-NDA may be adjacent to only one side of the display portion D-DA, or may be disposed on the side surface rather than the front surface of the display device DD. Without being limited thereto, the non-display portion D-NDA may be omitted.

The display device DD according to an embodiment may sense an external input applied from the outside (e.g., outside of the display device DD). The external input may have various forms, such as pressure, temperature, light, and the like, which are provided from the outside. The external input may include not only a touch input on the display device DD (e.g., a touch input by an input tool such as a body part like a hand of the user or a pen) but also an input applied in proximity to the display device DD (e.g., hovering).

Referring to FIG. 2, the display device DD may include a window WM, a display module DM, and an outer case HAU (or housing). The display module DM may include a display panel DP and a light control member LCM which is disposed on the display panel DP as a light control layer.

The window WM and the outer case HAU may be combined to form the exterior of the display device DD, and together may provide an inner space in which components of the display device DD, such as the display module DM, are accommodated.

The window WM may be disposed on the display module DM. The window WM may protect the display module DM from external shocks. The front surface of the window WM may correspond to (or define) the above-described display surface IS of the display device DD. The front surface of the window WM may include a transmissive area TA and a bezel area BA. The display device DD and various components or layers thereof may include a display portion D-DA, a non-display portion D-NDA, a transmissive area TA and/or a bezel area BA corresponding to those described above.

The transmissive area TA of the window WM may be an optically transparent area. Light may be transmitted through the window WM at the transmissive area TA. The window WM may transmit, through the transmissive area TA, an image IM provided by the display module DM, and the image IM may be visually recognized from outside the window WM. The transmissive area TA may correspond to the display portion D-DA (refer to FIG. 1) of the display device DD.

The window WM may contain (or include) an optically transparent insulating material. For example, the window WM may contain glass, sapphire, or plastic. The window WM may have a single-layer structure or a multi-layer structure. The window WM may further include at least one functional layer, such as an anti-fingerprint layer, a phase control layer, and a hard coating layer, which are disposed on an optically transparent substrate.

The bezel area BA of the window WM may be an area provided by depositing or printing a material having a predetermined color on a transparent substrate or by coating the transparent substrate with the material. The bezel area BA of the window WM may prevent a component of the display module DM disposed to overlap the bezel area BA from being visible from the outside. The bezel area BA may correspond to the non-display portion D-NDA (refer to FIG. 1) of the display device DD.

The display module DM may be disposed between the window WM and the outer case HAU. That is, the window WM may face the outer case HAU with the display module DM therebetween. The display module DM may display an image IM in response to an electrical signal applied to the display module DM. The display module DM may include a display area DA and a non-display area NDA adjacent to the display area DA.

The display area DA may be an area (e.g., planar area) activated in response to an electrical signal. The display area DA may be an area that outputs an image IM provided (or generated) by the display module DM. The display area DA of the display module DM may overlap the transmissive area TA. The image IM generated in the display area DA may be visible from the outside, through the transmissive area TA.

The non-display area NDA may be adjacent to the display area DA. For example, the non-display area NDA may surround the display area DA. However, without being limited thereto, the non-display area NDA may be defined in various shapes. The non-display area NDA may be an area in which a drive circuit or drive wiring for driving elements disposed in the display area DA, various types of signal lines providing electrical signals to the elements, and pads PD are disposed. The non-display area NDA of the display module DM may overlap the bezel area BA of the window WM, and the bezel area BA may prevent components of the display module DM disposed in the non-display area NDA from being visible from the outside.

The display panel DP according to an embodiment may be an emissive display panel, but is not particularly limited thereto. For example, the display panel DP may be an organic light emitting display panel, an inorganic light emitting display panel, or a quantum dot light emitting display panel. An emissive layer of the organic light emitting display panel may contain an organic light emitting material, and an emissive layer of the inorganic light emitting display panel may contain an inorganic light emitting material. An emissive layer of the quantum dot light emitting display panel may contain quantum dots, quantum rods, and the like. Hereinafter, it will be exemplified that the display panel DP is an organic light emitting display panel.

The light control member LCM may be disposed on the display panel DP. The light control layer may be disposed facing the display panel DP, such as facing the display area DA and/or the non-display area NDA of the display panel DP. The light control member LCM may be directly disposed on the display panel DP. The expression “directly disposed” used herein may mean that components are formed through a continuous process without a separate adhesive member (e.g., intervening member) therebetween. As being related “directly,” elements may form an interface therebetween, without being limited thereto. That is, the light control member LCM may be formed, through a continuous process, on a base surface provided by the display panel DP. Accordingly, the thickness of the display module DM may be decreased.

The light control member LCM as a light control layer may selectively transmit light provided by the display panel DP and/or may change the wavelength of the light. Furthermore, the light control member LCM as a light control layer may prevent reflection of external light incident from outside the display device DD.

The outer case HAU may be disposed under the display module DM and may accommodate the display module DM. The outer case HAU may absorb shocks applied to the display module DM from the outside and may protect the display module DM by preventing infiltration of foreign matter and/or moisture into the display module DM. The outer case HAU according to an embodiment may be provided in a form in which a plurality of storage members are combined together.

The display device DD may further include an input sensing module. The input sensing module may obtain information about the coordinates of an external input applied from outside the display device DD. The input sensing module of the display device DD may be driven in various ways, such as a capacitive detecting method, a resistive detecting method, an infrared detecting method, or a pressure detecting method, but is not limited thereto.

In an embodiment, the input sensing module may be disposed on the display module DM. The input sensing module may be directly disposed on the display module DM through a continuous process. However, without being limited thereto, the input sensing module may be manufactured (or provided) separately from the display module DM and may be attached to the display module DM by an adhesive layer as an intervening element. In an embodiment, the input sensing module may be disposed between components of the display module DM. For example, the input sensing module may be disposed between the display panel DP and the light control member LCM, or may be disposed inside the light control member LCM.

The display device DD may further include an electronic module including various functional modules for operating the display module DM, a power supply module that supplies power to the display device DD, and/or a bracket combined with the display module DM and/or the outer case HAU to divide the inner space of the display device DD.

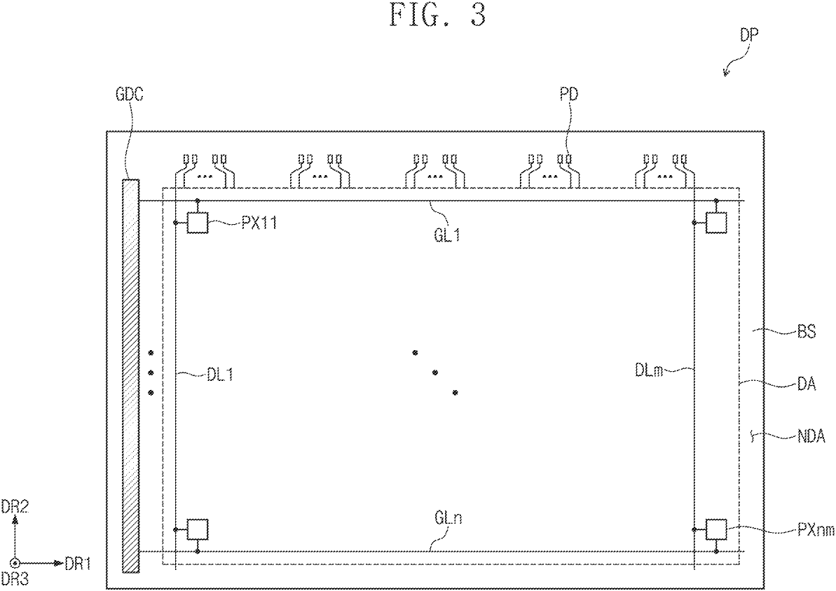

FIG. 3 is a plan view of the display panel DP according to an embodiment. Referring to FIG. 3, the display panel DP may include a base layer BS that provides a base surface on which components of the display panel DP are disposed. The base layer BS of the display panel DP may include a display area DA and a non-display area NDA.

Referring to FIG. 3, the display panel DP may include pixels PX11 to PXnm disposed in the display area DA and signal lines GL1 to GLn and DL1 to DLm which are electrically connected to the pixels PX11 to PXnm. The display panel DP may include a drive circuit GDC and a pad PD provided in plural including a plurality of pads PD disposed in the non-display area NDA.

Each of the pixels PX11 to PXnm may include a light emitting element OL and a pixel drive circuit including a plurality of transistors (e.g., a switching transistor and a drive transistor) which is connected to the light emitting element OL. The pixels PX11 to PXnm may generate and/or emit light in response to electrical signals applied to the pixels PX11 to PXnm. Although FIG. 3 illustrates the pixels PX11 to PXnm arranged in a matrix form, a form in which the pixels PX11 to PXnm are arranged is not limited thereto.

The signal lines GL1 to GLn and DL1 to DLm may include the gate lines GL1 to GLn and the data lines DL1 to DLm. Each of the pixels PX11 to PXnm may be connected to a corresponding one of the gate lines GL1 to GLn and a corresponding one of the data lines DL1 to DLm. The display panel DP may include more types of signal lines depending on the configuration of the pixel drive circuits that drive the pixels PX11 to PXnm.

The drive circuit GDC may include a gate drive circuit. The gate drive circuit may generate gate signals and may sequentially output the gate signals to the gate lines GL1 to GLn. The gate drive circuit may additionally output other control signals to the pixel drive circuits of the pixels PX11 to PXnm.

The pads PD may be arranged in one direction in (or along) the non-display area NDA. The pads PD may be portions of the display panel DP at which the display panel DP is connected to an external element such as a circuit board. Each of the pads PD may be connected with a corresponding signal line among the plurality of signal lines GL1 to GLn and DL1 to DLm and may be connected to a corresponding pixel through the corresponding signal lines. The pads PD may be integrated with the signal lines GL1 to GLn and DL1 to DLm, such as to be a portion of a respective signal line and/or in a same layer as the respective signal line. However, without being limited thereto, the pads PD may be disposed on (or in) a different layer from the signal lines GL1 to GLn and DL1 to DLm and may be connected with the signal lines GL1 to GLn and DL1 to DLm through contact holes.

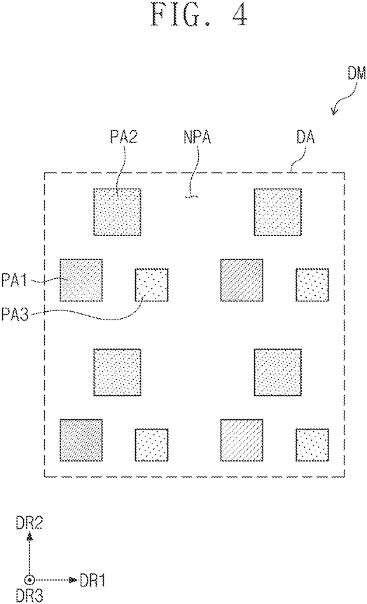

FIG. 4 is an enlarged plan view corresponding to the display area DA of the display module DM according to an embodiment. The display area DA of the display module DM may include pixel areas PA1, PA2, and PA3 corresponding to a plurality of light emitting elements, and a peripheral area NPA surrounding the pixel areas PA1, PA2, and PA3.

The pixel areas PA1, PA2, and PA3 may be areas (e.g., planar areas) through which light provided from the plurality of light emitting elements is emitted. The pixel areas PA1, PA2, and PA3 may include the first pixel area PA1, the second pixel area PA2, and the third pixel area PA3. The first to third pixel areas PA1, PA2, and PA3 may be distinguished depending on the colors of light emitted toward the outside of the display module DM. The peripheral area NPA may set the borders between the first to third pixel areas PA1, PA2, and PA3 which are respectively adjacent to each other and may prevent color mixing between the first to third pixel areas PA1, PA2, and PA3.

Among the first to third pixel areas PA1, PA2, and PA3, one may provide first color light corresponding to source light provided by a light emitting element OL, another one may provide second color light different from the first color light, and the remaining one may provide third color light different from the first color light and the second color light. For example, the first color light may be blue light, the second color light may be red light, and the third color light may be green light. However, examples of the color light are not necessarily limited thereto.

A plurality of first pixel areas PA1, a plurality of second pixel areas PA2, and a plurality of third pixel areas PA3 may be provided. The plurality of first pixel areas PA1, the plurality of second pixel areas PA2, and the plurality of third pixel areas PA3 may have a predetermined arrangement in the display area DA and may be repeatedly disposed. Referring to FIG. 4, the plurality of first pixel areas PA1, the plurality of second pixel areas PA2, and the plurality of third pixel areas PA3 may be arranged in the first direction DR1 and the second direction DR2.

The second pixel areas PA2 arranged side by side in the first direction DR1 may be defined as a first row (e.g., a first pixel row), and the first pixel areas PA1 and the third pixels areas PA3 arranged side by side in the first direction DR1 may be defined as a second row (e.g., a second pixel row). In the second row, the first pixel areas PA1 may alternate with the third pixel areas PA3 in the first direction DR1.

A plurality of first rows and a plurality of second rows may be provided. The plurality of first rows and the plurality of second rows may be arranged in the second direction DR2. The plurality of first rows may alternate with the plurality of second rows in the second direction DR2. Each of the various pixel areas may have a center along the first direction DR1 and/or the second direction DR2. A virtual axis (or virtual line) connecting the centers of the second pixel areas PA2 arranged in the second direction DR2, may be located between the first pixel area PA1 and the third pixel area PA3 which are adjacent (or closest) to each other along the first direction DR1.

However, the arrangement of the first to third pixel areas PA1, PA2, and PA3 illustrated in FIG. 4 is illustrative, and the first to third pixel areas PA1, PA2, and PA3 of the present disclosure may be arranged in various forms without being limited thereto.

The first to third pixel areas PA1, PA2, and PA3 may have various shapes on the plane (e.g., a planar shape). For example, each of the first to third pixel areas PA1, PA2, and PA3 may have a polygonal shape (e.g., a rectangular shape), a circular shape, an oval shape, or an irregular shape as various planar shapes.

The first to third pixel areas PA1, PA2, and PA3 may have the same shape on the plane. However, without being limited thereto, at least some of the first to third pixel areas PA1, PA2, and PA3 may have different shapes. FIG. 4 illustrates the first to third pixel areas PA1, PA2, and PA3 having a rectangular shape on the plane.

At least some of the first to third pixel areas PA1, PA2, and PA3 may have different planar areas. However, without being limited thereto, the first to third pixel areas PA1, PA2, and PA3 may have the same planar area. FIG. 4 illustrates the first to third pixel areas PA1, PA2, and PA3 having different planar areas.

The planar areas of the first to third pixel areas PA1, PA2, and PA3 may vary depending on the colors of emitted light. For example, a pixel area emitting green light may have the largest planar area, and a pixel area emitting blue light may have the smallest planar area. However, the difference in planar area between the pixel areas depending on the colors of emitted light is not limited thereto and may vary depending on the design of the display module DM.

The shapes, areas, and arrangements of the pixel areas PA1, PA2, and PA3 of the display module DM may be diversely designed depending on the colors of emitted light, the size of the display module DM, or configuration of the display module DM and are not limited to the embodiment illustrated in FIG. 4.

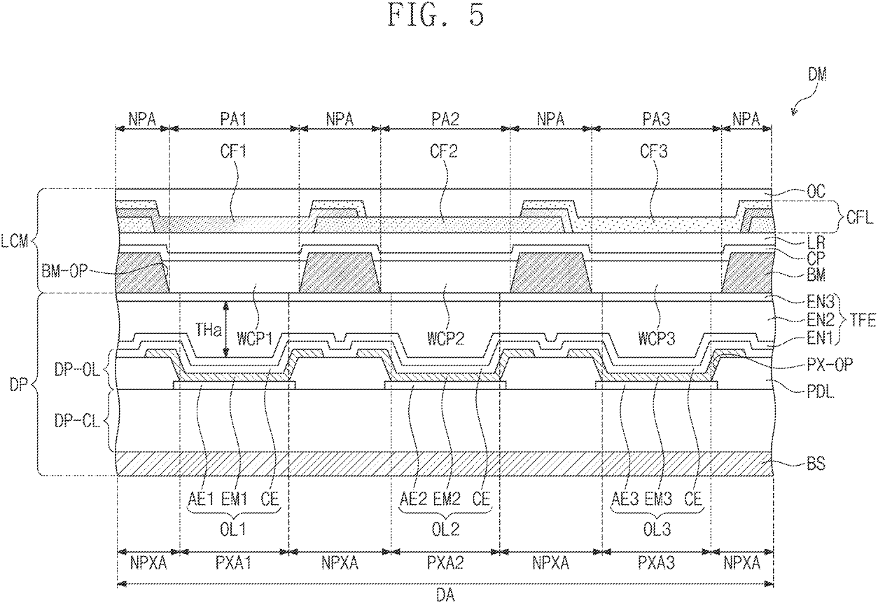

FIG. 5 is a cross-sectional view of the display module DM according to an embodiment. FIG. 5 illustrates a section of the display module DM corresponding to the first to third pixel areas PA1, PA2, and PA3. Referring to FIG. 5, the display module DM may include the display panel DP and the light control member LCM sequentially disposed in the thickness direction, such as in a direction away from the base layer BS.

Referring to FIG. 5, the display panel DP may include the base layer BS, a circuit layer DP-CL, a display element layer DP-OL, and an encapsulation layer TFE.

The base layer BS may provide a base surface for the circuit layer DP-CL and other layers of the display module DM. The base layer BS may include a glass substrate, a polymer substrate, or an organic/inorganic composite substrate. The base layer BS may have a single-layer structure or a multi-layer structure. For example, the base layer BS having the multi-layer structure may include synthetic resin layers and at least one inorganic layer disposed between the synthetic resin layers, or may include a glass substrate and a synthetic resin layer disposed on the glass substrate.

The synthetic resin layer of the base layer BS may contain at least one of an acryl-based resin, a methacryl-based resin, a polyisoprene-based resin, a vinyl-based resin, an epoxy-based resin, a urethane-based resin, a celluose-based resin, a siloxane-based resin, a polyamide-based resin, a perylene-based resin and a polyimide-based resin. However, the material of the base layer BS is not limited thereto.

The circuit layer DP-CL may be disposed on the base layer BS. The circuit layer DP-CL may include at least one insulating layer, a conductive pattern, and a semiconductor pattern. In manufacturing (or providing) of the display panel DP, an insulating layer, a semiconductor layer, and a conductive layer may be formed on the base layer BS by a method or process such as coating or deposition, and thereafter, the insulating layer, the semiconductor layer, and the conductive layer may be selectively subjected to patterning by photolithography to form the insulating layer, the semiconductor pattern, and the conductive pattern of the circuit layer DP-CL. The circuit layer DP-CL may include transistors of pixels, capacitors, and signal lines that are formed (or provided) by various portions of the insulating layer, the semiconductor pattern, and the conductive pattern.

The display element layer DP-OL may include light emitting elements OL1, OL2, and OL3 providing a light emitting element layer, and a pixel defining film PDL, that are disposed to overlap the display area DA. The light emitting elements OL1, OL2, and OL3 may be connected to and driven by the transistors of the circuit layer DP-CL and may provide source light (or, a first light) toward the light control member LCM in the display area DA.

For example, the light emitting elements OL1, OL2, and OL3 may include an organic light emitting element, an inorganic light emitting element, a quantum dot light emitting element, a micro light emitting diode (LED) light emitting element, or a nano LED light emitting element. Embodiments are not limited thereto, and the light emitting elements OL1, OL2, and OL3 may include various embodiments as long as light is generated, or the amount of light is controlled, in response to an electrical signal.

The light emitting elements OL1, OL2, and OL3 may include the first to third light emitting elements OL1, OL2, and OL3. The first light emitting element OL1 may include a first electrode AE1, an emissive part EM1 (e.g., emissive pattern or layer), and a second electrode CE sequentially stacked in a thickness direction from the base layer BS. The second light emitting element OL2 may include a first electrode AE2, an emissive part EM2, and the second electrode CE sequentially stacked one above another. The third light emitting element OL3 may include a first electrode AE3, an emissive part EM3, and the second electrode CE sequentially stacked one above another.

The first electrodes AE1, AE2, and AE3 of the first to third light emitting elements OL1, OL2, and OL3 may be disposed on the circuit layer DP-CL so as to be spaced apart from each other in a direction along the circuit layer DP-CL. The pixel defining film PDL may have (or define) a plurality of light emission openings PX-OP. The plurality of light emission openings PX-OP may correspond to the first electrodes AE1, AE2, and AE3, respectively, and may expose at least portions of the first electrodes AE1, AE2, and AE3 to outside the pixel defining film PDL. The first electrodes AE1, AE2, and AE3 of the first to third light emitting elements OL1, OL2, and OL3 exposed by the plurality of light emission openings PX-OP may correspond to first to third emissive areas PXA1, PXA2, and PXA3, respectively. The area in which the pixel defining film PDL is disposed may correspond to a non-emissive area NPXA (e.g., non-emission area) surrounding the first to third emissive areas PXA1, PXA2, and PXA3 (e.g. light emission areas).

The pixel defining film PDL may contain a polymer resin. For example, the pixel defining film PDL may contain a polyacrylate-based resin or a polyimide-based resin. The pixel defining film PDL may contain an inorganic material, in addition to the polymer resin. Alternatively, the pixel defining film PDL may contain an inorganic material. For example, the pixel defining film PDL may contain silicon nitride SiNₓ, silicon oxide SiOₓ, or silicon oxy-nitride SiOₓN_{y}.

In an embodiment, the pixel defining film PDL may contain a light absorbing material. The pixel defining film PDL may contain a black coloring agent. The black coloring agent may include a black dye or a black pigment. The black coloring agent may include carbon black, metal such as chromium, or oxide thereof. However, the pixel defining film PDL is not limited thereto.

The emissive parts EM1, EM2, and EM3 of the first to third light emitting elements OL1, OL2, and OL3 may be provided in the form of patterns disposed to correspond to the light emission openings PX-OP. The emissive parts EM1, EM2, and EM3 (e.g., emissive patterns) of the first to third light emitting elements OL1, OL2, and OL3 may include an emissive layer and a functional layer that controls electrons or holes to generate and/or emit light. Embodiments are not limited thereto, and the emissive parts EM1, EM2, and EM3 of the first to third light emitting elements OL1, OL2, and OL3 may be provided in an integrated form.

The emissive parts EM1, EM2, and EM3 may contain an organic light emitting material, an inorganic light emitting material, quantum dots, or quantum rods. The emissive parts EM1, EM2, and EM3 may generate the first light that is source light. For example, the first light may be blue light. In an embodiment, the emissive parts EM1, EM2, and EM3 of the first to third light emitting elements OL1, OL2, and OL3 may provide source light having different colors.

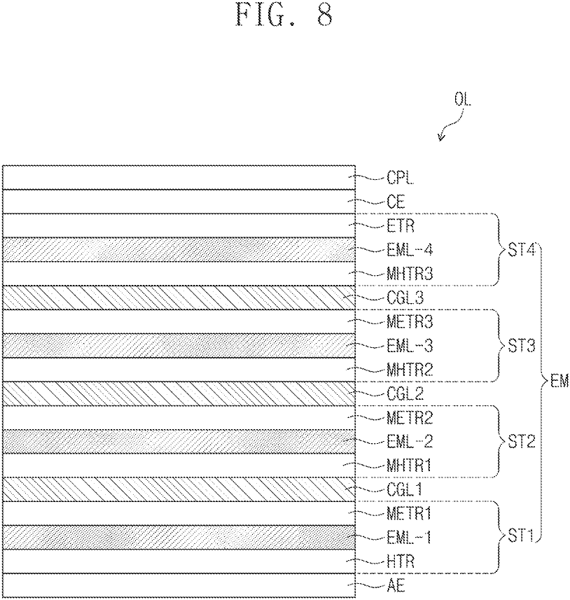

The first to third light emitting elements OL1, OL2, and OL3 may be light emitting elements having a tandem structure that include a plurality of emissive layers stacked on the corresponding first electrode AE1, AE2, and AE3. Detailed description thereabout will be given below with reference to FIG. 8.

The second electrode CE of the first to third light emitting elements OL1, OL2, and OL3 may be provided in an integrated form. That is, the second electrode CE of the first to third light emitting elements OL1, OL2, and OL3 may be provided in the form of a common layer. The second electrode CE may overlap the first to third emissive areas PXA1, PXA2, and PXA3 and the non-emissive area NPXA. A common voltage may be provided to the second electrode CE, and the second electrode CE may be referred to as the common electrode.

The encapsulation layer TFE may be disposed on the display element layer DP-OL and may seal the light emitting elements OL1, OL2, and OL3. The encapsulation layer TFE is between the plurality of light emitting elements (e.g., the first to third light emitting elements OL1, OL2, and OL3) and a corresponding light control part among the plurality of light control parts (e.g., light control parts WCP1, WCP2, and WCP3). The encapsulation layer TFE may include a plurality of insulating films EN1, EN2, and EN3. FIG. 5 illustrates the encapsulation layer TFE including the first to third insulating films EN1, EN2, and EN3. The first insulating film EN1 may be disposed on the light emitting elements OL1, OL2, and OL3, and the second insulating film EN2 and the third insulating film EN3 may be sequentially disposed on the first insulating film EN1 in a direction from the light emitting element layer toward the light control member LCM.

The first insulating film EN1 and the third insulating film EN3 may each include an inorganic film. The first insulating film EN1 and the third insulating film EN3, each of which includes the inorganic film, may protect the light emitting elements OL1, OL2, and OL3 from moisture and/or oxygen. For example, each of the first insulating film EN1 and the third insulating film EN3 may contain at least one of aluminum oxide, titanium oxide, silicon oxide, silicon nitride, silicon oxy-nitride, zirconium oxide and hafnium oxide, but is not limited thereto.

The second insulating film EN2 may include a low-refractive index organic film. The second insulating film EN2 may have a lower refractive index than light control parts WCP1, WCP2, and WCP3 as light control patterns, to be described below. For example, the second insulating film EN2 may have a refractive index of about 1.15 to about 1.35. The refractive index of the second insulating film EN2 may be adjusted by the percentage of hollow particles and/or voids contained in the organic film.

As the second insulating film EN2 includes the low-refractive index organic film, the second insulating film EN2 may totally reflect light output toward the light emitting elements OL1, OL2, and OL3 from the rear surfaces of the light control parts WCP1, WCP2, and WCP3 and may re-circulate the light into the light control parts WCP1, WCP2, and WCP3, thereby improving the light emission efficiency of the display module DM. As the second insulating film EN2 has a refractive index of 1.35 or less, the range of the incidence angle of light in which total reflection occurs may be expanded, and the second insulating film EN2 may totally reflect a larger amount of light beams among the light beams travelling from the light control parts WCP1, WCP2, and WCP3 and toward the light emitting elements OL1, OL2, and OL3. Accordingly, the light efficiency of the display module DM may be effectively improved. Detailed description thereabout will be given below.

As the second insulating film EN2 includes the low-refractive index organic film, the second insulating film EN2 may provide a flat upper surface, where the upper surface is furthest from the circuit layer DP-CL or the display element layer DP-OL. That is, the second insulating film EN2 may cover the stepped upper surface provided by the light emitting elements OL1, OL2, and OL3 and may provide a flat upper surface for components disposed on the second insulating film EN2 (e.g., may planarize the stepped upper surface). Accordingly, components of the light control member LCM formed on the second insulating film EN2 may be formed on a flat base surface, and the reliability of the display module DM may be improved. Furthermore, the second insulating film EN2 may cover the light emitting elements OL1, OL2, and OL3 to protect the light emitting elements OL1, OL2, and OL3 from foreign matter such as dust particles.

The second insulating film EN2 may have a predetermined thickness THa. The thickness THa of the second insulating film EN2 may correspond to an average separation distance between the lower surface and the upper surface of the second insulating film EN2 in the areas in which the light emitting elements OL1, OL2, and OL3 are disposed. In an embodiment, the thickness THa may be a maximum distance between the lower surface and the upper surface of the second insulating film EN2, and such maximum distance may correspond to the light emitting elements OL1, OL2, and OL3. The thickness THa may correspond to a respective first electrode and/or the respective emitting part on the respective first electrode, without being limited thereto. The thickness THa may correspond to a respective one of the light emission openings PX-OP, without being limited thereto. For example, the thickness THa of the second insulating film EN2 may range from about 1 micrometer (µm) to about 6 micrometers (µm). The thickness THa at each of the light emitting elements OL1, OL2, and OL3 may the same, without being limited thereto.

When the thickness THa of the second insulating film EN2 which corresponds to the light emitting elements OL1, OL2, and OL3 is less than 1 µm, the thickness THa may be insufficient to cover the light emitting elements OL1, OL2, and OL3 and to provide a flat upper surface, and a low-refraction effect may be decreased. Furthermore, the optical characteristics of the display module DM may be lowered. When the thickness THa of the second insulating film EN2 which corresponds to the light emitting elements OL1, OL2, and OL3 is 6 µm or more, the thickness of the encapsulation layer TFE and the thickness of the display module DM may be increased. As the thickness of the encapsulation layer TFE is increased, the distances between the light emitting elements OL1, OL2, and OL3 and the light control parts WCP1, WCP2, and WCP3 may be increased, and therefore the light emission efficiency may be lowered.

As the encapsulation layer TFE includes the second insulating film EN2 implemented with the low-refractive index organic film, the encapsulation layer TFE may have an effect of sealing and protecting the light emitting elements OL1, OL2, and OL3 and may minimize the amount of light lost in the direction toward the rear surfaces of the light control parts WCP1, WCP2, and WCP3 without a separate low-refractive index layer on the rear surfaces of the light control parts WCP1, WCP2, and WCP3. Accordingly, the problem of light loss may be solved without an increase in the distances between the light emitting elements OL1, OL2, and OL3 and the light control parts WCP1, WCP2, and WCP3 that affect the light emission efficiency, and the light emission efficiency may be effectively improved. Furthermore, since the thickness of the display module DM is not increased, the display module DM may be made thin, and the process and costs of manufacturing (or providing) the display module DM may be reduced.

The incidence angles at which light beams generated from the first to third light emitting elements OL1, OL2, and OL3 are incident on the light control parts WCP1, WCP2, and WCP3 may be controlled by controlling the thicknesses of the emissive parts EM1, EM2, and EM3 of the first to third light emitting elements OL1, OL2, and OL3. As the second insulating film EN2 includes the low-refractive index organic film, some of the light beams generated from the first to third light emitting elements OL1, OL2, and OL3 and output toward the light control parts WCP1, WCP2, and WCP3 may be reflected at (or by) the second insulating film EN2. However, the ratio of light beams corresponding to an incidence angle of 0 degrees to about 50 degrees, to a total of the light beams generated from the first to third light emitting elements OL1, OL2, and OL3, may be increased by controlling the thicknesses of the first to third light emitting elements OL1, OL2, and OL3. Accordingly, most of the light beams generated from the first to third light emitting elements OL1, OL2, and OL3 may pass through the second insulating film EN2 and may be incident toward the light control parts WCP1, WCP2, and WCP3, and the light emission efficiency may be improved. That is, without a decrease in the amount of light output from the first to third light emitting elements OL1, OL2, and OL3, the second insulating film EN2 may re-circulate light inside the light control parts WCP1, WCP2, and WCP2 to improve the final light emission efficiency of the display module DM.

Referring to FIG. 5, the light control member LCM may be directly disposed on the display panel DP. The light control member LCM may include a barrier rib BM (e.g., a plurality of barrier ribs in a layer), the light control parts WCP1, WCP2, and WCP3, a capping layer CP, a low-refractive index layer LR, a color filter layer CFL, and an over-coating layer OC.

The barrier rib BM may be disposed on the encapsulation layer TFE. The barrier rib BM may be disposed on the base surface provided by the encapsulation layer TFE. The barrier rib BM may contact with the respective insulating film disposed at the top of the encapsulation layer TFE. For example, in the embodiment of FIG. 5, the barrier rib BM may contact with the third insulating film EN3 of the encapsulation layer TFE.

The barrier rib BM may have (or define) a plurality of openings BM-OP defined therein. The plurality of openings BM-OP may be formed (or provided) in the layer of the barrier rib BM to correspond to the emissive areas PXA1, PXA2, and PXA3. The barrier rib BM may overlap (or corresponding to) the non-emissive area NPXA. The areas in which the plurality of openings BM-OP are formed may be defined as the pixel areas PA1, PA2, and PA3 described above.

The barrier rib BM may include a base resin and an additive. The additive may include a coupling agent and/or a photo-initiator. The additive may further include a dispersing agent. The barrier rib BM may contain a material having a predetermined color. For example, the barrier rib BM may contain a black dye or a black pigment. The barrier rib BM may set the borders between the first light control part WCP1, the second light control part WCP2, and the third light control part WCP3 to prevent color mixing.

The first pixel area PA1 may correspond to the first emissive area PXA1 and may have a planar area greater than or equal to the planar area of the first emissive area PXA1. The second pixel area PA2 may correspond to the second emissive area PXA2 and may have a planar area greater than or equal to the planar area of the second emissive area PXA2. The third pixel area PA3 may correspond to the third emissive area PXA3 and may have a planar area greater than or equal to the planar area of the third emissive area PXA3.

The light control parts WCP1, WCP2, and WCP3 may include the first to third light control parts WCP1, WCP2, and WCP3 disposed to correspond to the first to third pixel areas PA1, PA2, and PA3. The first to third light control parts WCP1, WCP2, and WCP3 may be surrounded by the barrier rib BM. The first to third light control parts WCP1, WCP2, and WCP3 may be in a color control layer along with the barrier wall patterns (e.g., barrier rib BM).

The first light control part WCP1 may be disposed to overlap the first light emitting element OL1. The second light control part WCP2 may be disposed to overlap the second light emitting element OL2. The third light control part WCP3 may be disposed to overlap the third light emitting element OL3. Accordingly, the first to third light control parts WCP1, WCP2, and WCP3 may be disposed to correspond to the first to third emissive areas PXA1, PXA2, and PXA3.

At least one of the first to third light control parts WCP1, WCP2, and WCP3 may be provided as a transmissive part that transmits source light provided from a light emitting element. Although it is exemplified in this embodiment that the third light control part WCP3 is provided as the transmissive part, embodiments are not necessarily limited thereto.

Each of the first light control part WCP1 and the second light control part WCP2 may include a base resin and quantum dots which are dispersed in the base resin. The quantum dots may be particles that convert the wavelength range of source light (e.g., wavelength-convert light). For example, the first light control part WCP1 (e.g., a color-conversion part) may include first quantum dots QD1, and the first quantum dots QD1 may convert a first light provided by the first light emitting element OL1 into a second light having a wavelength range different from the wavelength range of the first light. The second light control part WCP2 may include second quantum dots, and the second quantum dots may convert a first light provided by the second light emitting element OL2 into a third light having a wavelength range different from the wavelength range of the first light. Here, the second light and the third light may have different wavelength ranges.

For example, each of the first light emitting element OL1 and the second light emitting element OL2 may provide the first light, and in an embodiment, the first light may be blue light. The first quantum dots QD1 of the first light control part WCP1 may convert the first light provided from the first light emitting element OL1 into red light. The second quantum dots of the second light control part WCP2 may convert the first light provided from the second light emitting element OL2 into green light. However, embodiments are not necessarily limited thereto.

Cores of the quantum dots included in the first light control part WCP1 and the second light control part WCP2 may be selected from a Group II-VI compound, a Group III-VI compound, a Group I-III-VI compound, a Group III-V compound, a Group IV-VI compound, a Group IV element, a Group IV compound, and combinations thereof.

The Group II-VI compound may be selected from a binary compound of CdSe, CdTe, CdS, ZnS, ZnSe, ZnTe, ZnO, HgS, HgSe, HgTe, MgSe, MgS and mixtures (or combinations) thereof, a ternary compound selected from CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS and mixtures thereof, and a quarternary compound selected from HgZnTeS, CdZnSeS, CdZnSeTe, CdZnSTe, CdHgSeS, CdHgSeTe, CdHgSTe, HgZnSeS, HgZnSeTe, HgZnSTe and mixtures thereof.

The Group III-VI compound may include a binary compound such as In2S3 or In2Se3, a ternary compound such as InGaS3 or InGaSe3, or any combination thereof.

The Group I-III-VI compound may be selected from a ternary compound of AgInS, AgInS2, CuInS, CuInS2, AgGaS2, CuGaS2, CuGaO2, AgGaO2, AgAlO2 and mixtures thereof or a quarternary compound such as AgInGaS2 or CuInGaS2.

The Group III-V compound may be selected from a binary compound of GaN, GaP, GaAs, GaSb, AlN, AlP, AlAs, AlSb, InN, InP, InAs, InSb and mixtures thereof, a ternary compound of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb and mixtures thereof, and a quarternary compound of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb and mixtures thereof. The Group III-V compound may further include Group II metal. For example, InZnP may be selected as a Group III-II-V compound.

The Group IV-VI compound may be selected from a binary compound of SnS, SnSe, SnTe, PbS, PbSe, PbTe and mixtures thereof, a ternary compound of SnSeS, SnSeTe, SnSTe, PbSeS, PbSeTe, PbSTe, SnPbS, SnPbSe, SnPbTe and mixtures thereof, and a quarternary compound of SnPbSSe, SnPbSeTe, SnPbSTe and mixtures thereof. The Group IV element may be selected from Si, Ge and a mixture thereof. The Group IV compound may be a binary compound selected from SiC, SiGe and a mixture thereof.

In this case, the binary compound, the ternary compound, or the quarternary compound may exist in the particle in uniform concentration, or may exist in the same particle with partially different concentration distribution.

The quantum dots may have a core-shell structure that includes a core and a shell which surrounds the core. Alternatively, in an embodiment, the quantum dots may have a core/shell structure in which one quantum dot surrounds another quantum dot. The interface between the core and the shell may have a concentration gradient in which the concentration of an element existing in the shell is lowered toward the center.

In an embodiment, the quantum dots may have the aforementioned core-shell structure including a nanocrystal. The shell of each quantum dot may serve as a protective layer for maintaining semiconductor characteristics by preventing chemical modification of the core and/or a charging layer for imparting electrophoretic characteristics to the quantum dot. The shell may have a single layer or multiple layers. The interface between the core and the shell may have a concentration gradient in which the concentration of an element existing in the shell is lowered toward the center. The shell of the quantum dot may be exemplified by metal oxide, non-metal oxide, a semiconductor compound, or a combination thereof.

For example, the metal oxide and the non-metal oxide may include, but are not limited to, a binary compound such as SiO₂, AL₂O₃, TiO₂, ZnO, MnO, Mn₂O₃, CuO, FeO, Fe₂O₃, Fe₃O₄, CoO, Co₃O₄, or NiO, or a ternary compound such as MgAl₂O₄, CoFe₂O₄, NiFe₂O₄, or CoMn₂O₄.

The semiconductor compound may include, but is not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, or AlSb.

The quantum dot may have a full width at half maximum (FWHM) of a light emission wavelength spectrum that is about 45 nm or less, such as about 40 nm or less or about 30 nm or less, and may improve color purity or color reproduction in the range. Furthermore, light emitted through the quantum dot may be emitted in all directions, and thus a wide viewing angle may be improved.

The form of the quantum dot is not particularly limited to a form generally used in the related art. For example, a nanoparticle, a nanotube, a nanowire, a nanofiber, or a nanoplatelet particle that has a spherical, pyramidal, multi-arm, or cubic shape may be used.

The quantum dot may adjust the color of emitted light depending on the particle size. Accordingly, the quantum dot may have various light emission colors such as blue, red, and green. When the above-described emissive layer contains a quantum-dot material, the above description of the quantum dot may be identically applied to the quantum-dot material contained in the emissive layer.

The third light control part WCP3 may be provided as a transmissive part and may transmit the first light provided by the third light emitting element OL3, without color-conversion or color change. For example, the third light emitting element OL3 may provide blue light, and the blue light may be output toward the front surface of the display module DM through the third light control part WCP3.

The third light control part WCP3 may include a base resin and may further include scattering particles dispersed in the base resin. In an embodiment, the first light control part WCP1 and the second light control part WCP2 may also further include scattering particles.

The scattering particles may scatter light converted in the light control parts WCP1, WCP2, and WCP3 or light passing through the light control parts WCP1, WCP2, and WCP3 in various directions. The scattering particles may be particles having a relatively high density or specific gravity. The scattering particles may include titanium oxide TiO₂ or silica-based nanoparticles. As the light control parts WCP1, WCP2, and WCP3 include the scattering particles, the light conversion efficiency by the quantum dots in the light control parts WCP1, WCP2, and WCP3 may be improved, and the light emission efficiency may be improved.

The display module DM according to an embodiment may output red light through the first pixel area PA1, may output green light through the second pixel area PA2, and may output blue light through the third pixel area PA3. The display module DM may display a predetermined image in the display area DA through the first to third pixel areas PA1, PA2, and PA3 that display red, green, and blue. However, the colors of light output through the first to third pixel areas PA1, PA2, and PA3 are not necessarily limited thereto.

The capping layer CP may be disposed on the light control parts WCP1, WCP2, and WCP3 and the barrier rib BM. The capping layer CP may contain an inorganic material. The capping layer CP may prevent infiltration of moisture or foreign matter into the light control parts WCP1, WCP2, and WCP3. The light control member LCM may further include an additional capping layer disposed between the low-refractive index layer LR and the color filter layer CFL, and the additional capping layer may protect the low-refractive index layer LR and color filters CF1, CF2, and CF3.

The low-refractive index layer LR may be disposed on the light control parts WCP1, WCP2, and WCP3. The low-refractive index layer LR may include a low-refractive index organic film. The low-refractive index layer LR may further include scattering particles dispersed in the organic film. The low-refractive index layer LR may have a lower refractive index than a refractive index of the light control parts WCP1, WCP2, and WCP3. For example, the low-refractive index layer LR may have a refractive index of about 1.1 to about 1.5. In an embodiment, the low-refractive index layer LR may have a refractive index of about 1.1 to about 1.35.

The low-refractive index layer LR may contain a material having a high light transmittance. For example, the low-refractive index layer LR may have a high transmittance of about 90% or more. As the low-refractive index layer LR has a high transmittance, travel of light output from the light control parts WCP1, WCP2, and WCP3 toward the front surface of the display module DM may not be obstructed.

The low-refractive index layer LR may include a low-refractive index organic film that is the same as the low-refractive index organic film included in the second insulating film EN2 of the encapsulation layer TFE. However, without being limited thereto, the material included in the low-refractive index layer LR may differ from the low-refractive index organic film included in the second insulating film EN2 of the encapsulation layer TFE. The low-refractive index layer LR may be disposed on the upper surfaces of the light control parts WCP1, WCP2, and WCP3. The low-refractive index layer LR may circulate light into the light control parts WCP1, WCP2, and WCP3 and may minimize light output without being converted by the light control parts WCP1, WCP2, and WCP3, thereby improving the light emission efficiency of the display module DM.

The second insulating film EN2 of the encapsulation layer TFE, which is disposed under the light control parts WCP1, WCP2, and WCP3 and includes the low-refractive index organic film, may be defined as the first low-refractive index film. The low-refractive index layer LR disposed above the light control parts WCP1, WCP2, and WCP3 may be defined as the second low-refractive index film. As the display module DM according to an embodiment includes the first low-refractive index film and the second low-refractive index film disposed under and above the light control parts WCP1, WCP2, and WCP3, an effect of re-circulating light into the light control parts WCP1, WCP2, and WCP3 may be maximized. Accordingly, the light emission efficiency of the display module DM may be improved.

However, in an embodiment, the low-refractive index layer LR may be omitted from the display module DM.

The color filter layer CFL may be disposed on the low-refractive index layer LR. The color filter layer CFL may include the first color filter CF1, the second color filter CF2, and the third color filter CF3. The first to third color filters CF1, CF2, and CF3 may be disposed to correspond to the first to third pixel areas PA1, PA2, and PA3, respectively.

Each of the first to third color filters CF1, CF2, and CF3 may include a base resin and a pigment or dye which is dispersed in the base resin. Each of the first to third color filters CF1, CF2, and CF3 may transmit light having a specific wavelength range and may absorb light having a wavelength range other than the specific wavelength range.

For example, among the first to third color filters CF1, CF2, and CF3, one may include a red color filter, another one may include a green color filter, and the remaining one may include a blue color filter. The red color filter may transmit red light and may absorb most of green light and blue light. The green color filter may transmit green light and may absorb most of red light and blue light. The blue color filter may transmit blue light and may absorb most of red light and green light.

The first color filter CF1 may be disposed on the first light control part WCP1. The first color filter CF1 may transmit the second light provided from the first light control part WCP1. For example, the first light control part WCP1 may convert blue light provided from the first light emitting element OL1 into red light, and the first color filter CF1 may transmit the red light provided from the first light control part WCP1. The first color filter CF1 may absorb blue light and green light incident toward the first color filter CF1. Accordingly, the first color filter CF1 may absorb light beams not converted by the first light control part WCP1 among light beams incident toward the first color filter CF1, thereby preventing deterioration in color purity in the first pixel area PA1.

Likewise, the second color filter CF2 may be disposed on the second light control part WCP2 and may transmit the third light provided from the second light control part WCP2. For example, the second light control part WCP2 may convert blue light provided from the second light emitting element OL2 into green light, and the second color filter CF2 may transmit the green light provided from the second light control part WCP2. The second color filter CF2 may absorb red light and blue light incident toward the second color filter CF2.

The third color filter CF3 may be disposed on the third light control part WCP3 and may transmit the first light passing through the third light control part WCP3. For example, the third light control part WCP3 may transmit blue light provided from the third light emitting element OL3, and the third color filter CF3 may transmit the blue light passing through the third light control part WCP3.

External light, such as natural light, may be incident toward the display panel DP from outside the display module DM (e.g., a direction opposite to the light-emitting direction of the display module DM). The external light may include red light, green light, and blue light. If the display module DM does not include the color filter layer CFL, the external light incident toward the display panel DP may be reflected by conductive patterns (e.g., signal lines and electrodes) in the display panel DP and may be provided back to outside the display panel DP to be visually recognized as reflected light. However, as the display module DM includes the color filter layer CFL, the reflectivity of the external light by the display module DM may be decreased.

Specifically, the first to third color filters CF1, CF2, and CF3 may prevent reflection of the external light. The first color filter CF1, which transmits the second light, may absorb light beams corresponding to the wavelength ranges of the first light and the third light among light beams provided from the outside. For example, the first color filter CF1 may be a red color filter. The first color filter CF1 may filter the external light into red light by absorbing green light and blue light of the external light. Likewise, the second color filter CF2 may be a green color filter. The second color filter CF2 may filter the external light into green light by absorbing red light and blue light of the external light. The third color filter CF3 may be a blue color filter. The third color filter CF3 may filter the external light into blue light by absorbing red light and green light of the external light.

The first to third color filters CF1, CF2, and CF3 according to an embodiment may overlap each other in the peripheral area NPA. For example, the first to third color filters CF1, CF2, and CF3 may be disposed to overlap each other in the thickness direction in the peripheral area NPA. The first to third color filters CF1, CF2, and CF3 disposed to overlap each other may function as a light-blocking area to block light passing through the peripheral area NPA to prevent color mixing between the first to third pixel areas PA1, PA2, and PA3. FIG. 5 illustrates the color filters CF1, CF2, and CF3 disposed to overlap each other in the peripheral area NPA. However, without being limited thereto, the color filters CF1, CF2, and CF3 may be spaced apart from each other with the peripheral area NPA therebetween.

The color filter layer CFL may further include a bank that surrounds the first to third color filters CF1, CF2, and CF3 and sets the borders between the first to third color filters CF1, CF2, and CF3. The bank of the color filter layer CFL may contain a material, such as a black pigment or a black dye, which has a predetermined color. The bank of the color filter layer CFL may absorb light to prevent color mixing (e.g., such as to provide a light-blocking function).

The over-coating layer OC may be disposed on the color filter layer CFL. The over-coating layer OC may include an organic layer. The over-coating layer OC may contain an optically transparent material. The over-coating layer OC may be formed (or provided) by coating the color filters CF1, CF2, and CF3 with the organic layer. The over-coating layer OC may cover steps between the color filters CF1, CF2, and CF3 of the color filter layer CFL and may provide a flat upper surface.

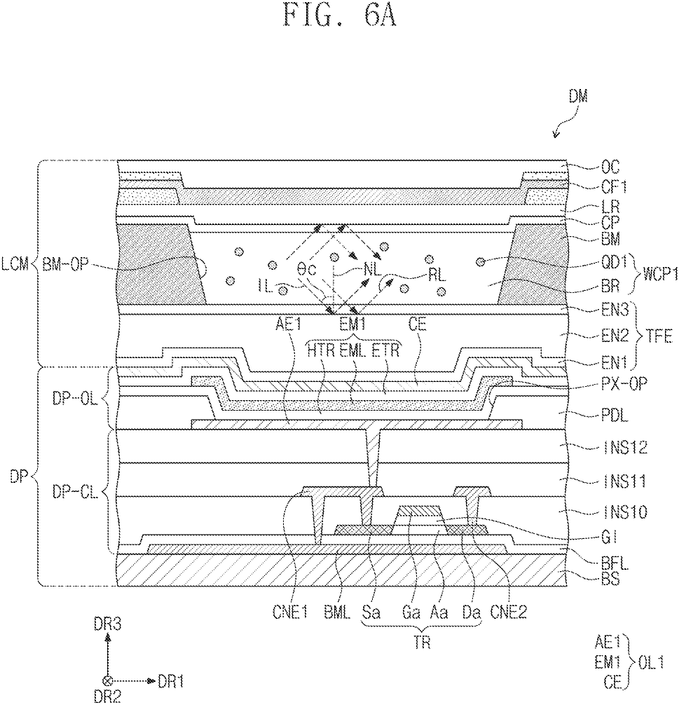

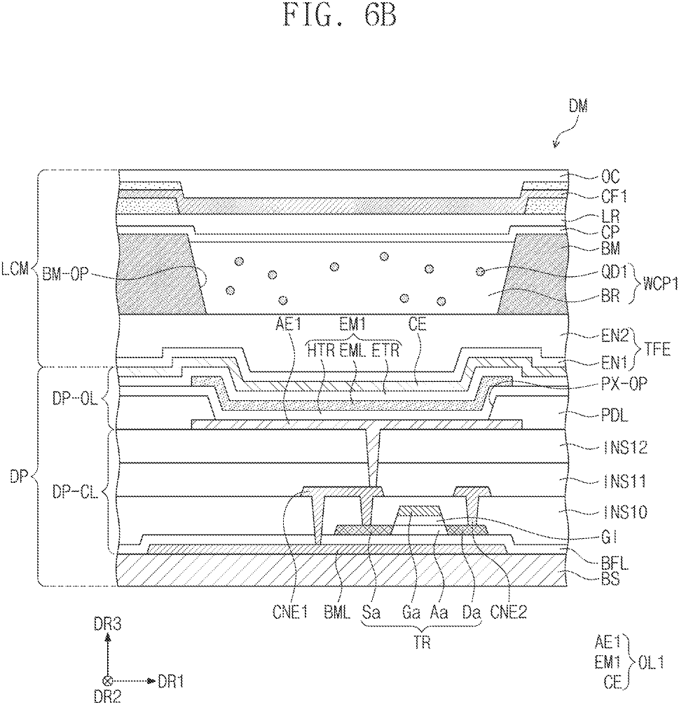

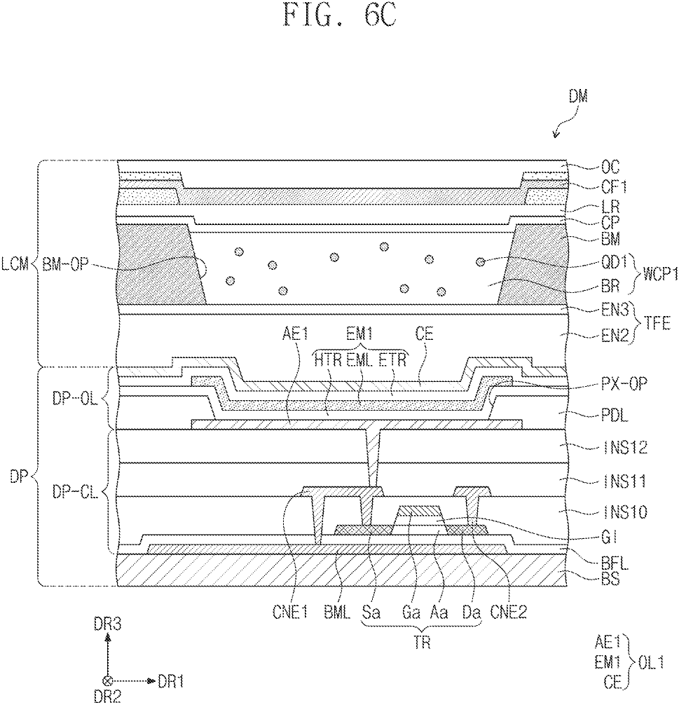

FIGS. 6A to 6C are cross-sectional views of the display module DM according to embodiments. FIGS. 6A to 6C illustrate enlarged sectional views corresponding to the first pixel area PA1 among the first to third pixel areas PA1, PA2, and PA3. Corresponding description may be applied to the second and third pixel areas PA2 and PA3. The embodiments of FIGS. 6A to 6C include substantially the same configuration as the above-described display module DM, and there is a difference in some configurations. The following description will be focused on the differences of the embodiments.

The circuit layer DP-CL may include a semiconductor pattern and a conductive pattern that are disposed according to a predetermined rule across pixels depending on an equivalent circuit configuration of a pixel, and transistors and electrodes may be formed from the semiconductor pattern and the conductive pattern. In FIGS. 6A to 6C, one transistor TR included in the pixel is illustrated.

Referring to FIGS. 6A to 6C, the circuit layer DP-CL may include a light blocking pattern BML, the transistor TR, connecting electrodes CNE1 and CNE2, an insulating pattern GI, and a plurality of insulating layers INS10, INS11, and INS12.

The light blocking pattern BML may be disposed on the base layer BS. The light blocking pattern BML may overlap the transistor TR. The light blocking pattern BML may prevent conductive patterns included in the circuit layer DP-CL from being visible due to external light, or may prevent damage to a semiconductor pattern included in the transistor TR due to external light.

The circuit layer DP-CL may further include a buffer layer BFL disposed on the base layer BS. The buffer layer BFL may cover the light blocking pattern BML. The buffer layer BFL may improve the bonding force between the base layer BS and the semiconductor pattern.

The buffer layer BFL may contain an inorganic material. For example, the buffer layer BFL may contain at least one of aluminum oxide, titanium oxide, silicon oxide, silicon nitride, silicon oxy-nitride, zirconium oxide and hafnium oxide. However, the material of the buffer layer BFL is not limited thereto.

The semiconductor pattern of the transistor TR may be disposed on the buffer layer BFL. The semiconductor pattern may contain poly silicon. However, without being limited thereto, the semiconductor pattern may contain amorphous silicon, crystalline oxide, or non-crystalline oxide.

A source area Sa, a drain area Da, and a channel area Aa of the transistor TR may be formed from the semiconductor pattern. The semiconductor pattern may be divided into a plurality of areas depending on conductivities. For example, the semiconductor pattern may have different electrical properties depending on whether doping is performed or whether metal oxide is reduced. A high-conductivity area in the semiconductor pattern may serve as an electrode or a signal line and may correspond to the source area Sa and the drain area Da of the transistor TR. A non-doped or non-reduced area having relatively low conductivity may correspond to the channel area Aa (or, the active area) of the transistor TR.

The insulating pattern GI may be disposed on the semiconductor pattern of the transistor TR. The insulating pattern GI may be formed by forming an insulating material layer on the semiconductor pattern of the transistor TR and thereafter making the insulating material layer subjected to patterning. A gate electrode Ga may be disposed on the insulating pattern GI. The gate electrode Ga may be used as a mask in the process of forming the insulating pattern GI. The gate electrode Ga may overlap the channel area Aa and, on the section, may be spaced apart from the semiconductor pattern of the transistor TR with the insulating pattern GI therebetween.

The plurality of insulating layers INS10, INS11, and INS12 may be disposed on the buffer layer BFL, where one or more of these layers may together define “an insulating layer.” Each of the plurality of insulating layers INS10, INS11, and INS12 may include at least one inorganic layer or at least one organic layer. For example, the inorganic layer of each of the insulating layers INS10, INS11, and INS12 may contain at least one of aluminum oxide, titanium oxide, silicon oxide, silicon nitride, silicon oxy-nitride, zirconium oxide and hafnium oxide, but is not limited thereto. The organic layer of each of the insulating layers INS10, INS11, and INS12 may contain a phenol-based polymer, an acryl-based polymer, an imide-based polymer, an aryl ether-based polymer, an amide-based polymer, a fluorine-based polymer, a p-xylene-based polymer, a vinyl alcohol-based polymer, or a polymer obtained by a combination thereof, but is not limited thereto.

The first insulating layer INS10 may be disposed on the buffer layer BFL and may cover the gate electrode Ga. The first insulating layer INS10 may have a contact hole defined therein for exposing a portion of the semiconductor pattern of the transistor TR to outside the first insulating layer INS10.

The connecting electrodes CNE1 and CNE2 may include the first connecting electrode CNE1 and the second connecting electrode CNE2 each disposed on the first insulating layer INS10. The first connecting electrode CNE1 may be connected to the source area Sa of the transistor TR through a contact hole penetrating the first insulating layer INS10. In an embodiment, the first connecting electrode CNE1 may be connected to the light blocking pattern BML through a contact hole penetrating the first insulating layer INS10 and the buffer layer BFL. The second connecting electrode CNE2 may be connected to the drain area Da of the transistor TR through a contact hole penetrating the first insulating layer INS10. The second connecting electrode CNE2 may extend on the plane (e.g., along the first direction DR1 and the second direction DR2) and may be connected to another transistor or wiring.

The second insulating layer INS11 and the third insulating layer INS12 may be disposed in order on the first insulating layer INS10 to cover the connecting electrodes CNE1 and CNE2. A through-hole exposing a portion of the first connecting electrode CNE1 may be defined in the second insulating layer INS11 and the third insulating layer INS12 as individual through-holes aligned with each other, and the first connecting electrode CNE1 may be connected to the first electrode AE1 of the first light emitting element OL1 disposed on the third insulating layer INS12. In an embodiment, the third insulating layer INS12 may include an organic film and may provide a flat upper surface. However, embodiments are not necessarily limited thereto.

Referring to FIGS. 6A to 6C, the emissive part EM1 of the first light emitting element OL1 may include a hole control layer HTR, an emissive layer EML, and an electron control layer ETR. Descriptions thereabout may be identically applied to the emissive parts EM2 and EM3 of the second and third light emitting elements OL2 and OL3.

The hole control layer HTR may be disposed on the first electrode AE1 and the pixel defining film PDL. The hole control layer HTR may be commonly disposed for a plurality of pixels. The hole control layer HTR may commonly overlap the first to third light emitting elements OL1, OL2, and OL3 (refer to FIG. 5). The hole control layer HTR may include at least one of a hole transporting layer and a hole injection layer.

The electron control layer ETR may be disposed between the emissive layer EML and the second electrode CE. The electron control layer ETR may be commonly disposed for the plurality of pixels. The electron control layer ETR may commonly overlap the first to third light emitting elements OL1, OL2, and OL3 (refer to FIG. 5). The electron control layer ETR may include at least one of an electron transporting layer and an electron injection layer.

The emissive layer EML may contain an organic light emitting material or an inorganic light emitting material and may emit light. Through the transistor TR, a first voltage may be applied to the first electrode AE1, and a common voltage may be applied to the second electrode CE. Holes and electrons injected into the emissive layer EM1, may be combined to form excitons, and the light emitting element OL1 may emit light as the excitons transition to a ground state.

The encapsulation layer TFE illustrated in FIG. 6A may include the first to third insulating films EN1, EN2, and EN3 as illustrated in FIG. 5. The first insulating film EN1 and the third insulating film EN3 may include an inorganic film, and the second insulating film EN2 may include a low-refractive index organic film. The second insulating film EN2 may cover a step on the upper surface of the display element layer DP-OL and may provide a flat upper surface. The above description may be identically applied to description of the first to third insulating films EN1, EN2, and EN3.

The embodiments illustrated in FIGS. 6B and 6C include substantially the same configuration as the embodiment illustrated in FIG. 6A. However, there is a difference in the configuration of the encapsulation layer TFE. Referring to FIG. 6B, the encapsulation layer TFE may include the first insulating film EN1 and the second insulating film EN2 disposed on the first insulating film EN1. The first insulating film EN1 may include an inorganic film, and the second insulating film EN2 may include a low-refractive index organic film. This may correspond to the omission of the third insulating film EN3 of the encapsulation layer TFE of FIG. 6A. Accordingly, the deposition process of the third insulating film EN3 may be omitted, and thus the manufacturing process of the encapsulation layer TFE may be simplified. In addition, the thickness of the encapsulation layer TFE may be decreased. Accordingly, the distance between the first light emitting element OL1 and the first light control part WCP1 may be decreased, and the light emission efficiency may be improved.

Referring to FIG. 6B, the light control member LCM may be directly disposed on the second insulating film EN2 of the encapsulation layer TFE. The light control member LCM may be formed on the base surface provided by the second insulating film EN2. In an embodiment, the barrier rib BM of the light control member LCM may contact with the second insulating film EN2.

The configuration of the encapsulation layer TFE is not limited thereto. Referring to FIG. 6C, the first insulating film EN1 of the encapsulation layer TFE of FIG. 6A may be omitted, and the encapsulation layer TFE may include the second insulating film EN2 and the third insulating film EN3 disposed on the second insulating film EN2. The second insulating film EN2 may include a low-refractive index organic film, and the third insulating film EN3 may include an inorganic film. In an embodiment, the second insulating film EN2 may be directly disposed on the first light emitting element OL1. Accordingly, the deposition process of the first insulating film EN1 may be omitted, and thus the manufacturing process of the encapsulation layer TFE may be simplified. In addition, the thickness of the encapsulation layer TFE may be decreased.

As described above, the first light control part WCP1 may include a base resin BR and first quantum dots QD1 dispersed in the base resin BR. FIG. 6A schematically illustrates an optical path circulating within the first light control part WCP1. The following description will be given based on the first light control part WCP1. However, the corresponding description may be applied to the second and third light control parts WCP2 and WCP3.

Referring to FIG. 6A, some light beams IL within the first light control part WCP1 (hereinafter, referred to as the incident light beams IL) may be output from the first light control part WCP1 and toward the first light emitting element OL1 by the first quantum dots QD1 and scattering particles (not illustrated) that are dispersed in the first light control part WCP1.

The second insulating film EN2 including the low-refractive index organic film may have a lower refractive index than each of the third insulating film EN3 and the first light control part WCP1 that are disposed on the second insulating film EN2. As the second insulating film EN2 has a low refractive index, the second insulating film EN2 may totally reflect light beams having an incidence angle greater than or equal to a critical angle θc among the incident light beams IL incident on the second insulating film EN2, and the totally reflected light beams RL may be incident into the first light control part WCP1. Here, the critical angle θc corresponds to the included angle (or, the incidence angle) between the virtual normal line NL to the plane of incidence of the incident light beam IL and the incident light beam IL, and refers to a minimum incidence angle at which the incident light beam IL is totally reflected (e.g. a total reflection angle).

The critical angle θc may be decreased as the refractive index of the second insulating film EN2 is decreased. The amount of light beams totally reflected toward the first light control part WCP1 among the incident light beams IL incident on the second insulating film EN2 may be increased as the critical angle θc is decreased. For example, the second insulating film EN2 may have a refractive index of 1.35 or less, and the critical angle θc may be about 20 degrees. The critical angle θc of an encapsulation film according to an embodiment that has a higher refractive index than the second insulating film EN2 may be about 40 degrees. As the second insulating film EN2 has a lower refractive index than the encapsulation film according to the embodiment, the second insulating film EN2 may totally reflect incident light beams IL having an incidence angle of 20 degrees to 40 degrees, and thus the amount of light re-circulated into the first light control part WCP1 may be increased. Accordingly, the light emission efficiency may be effectively improved.

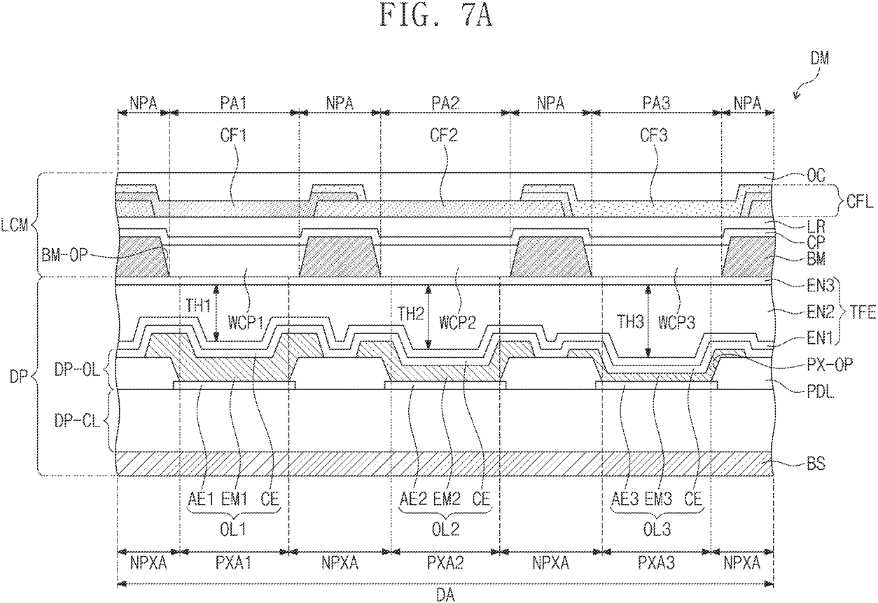

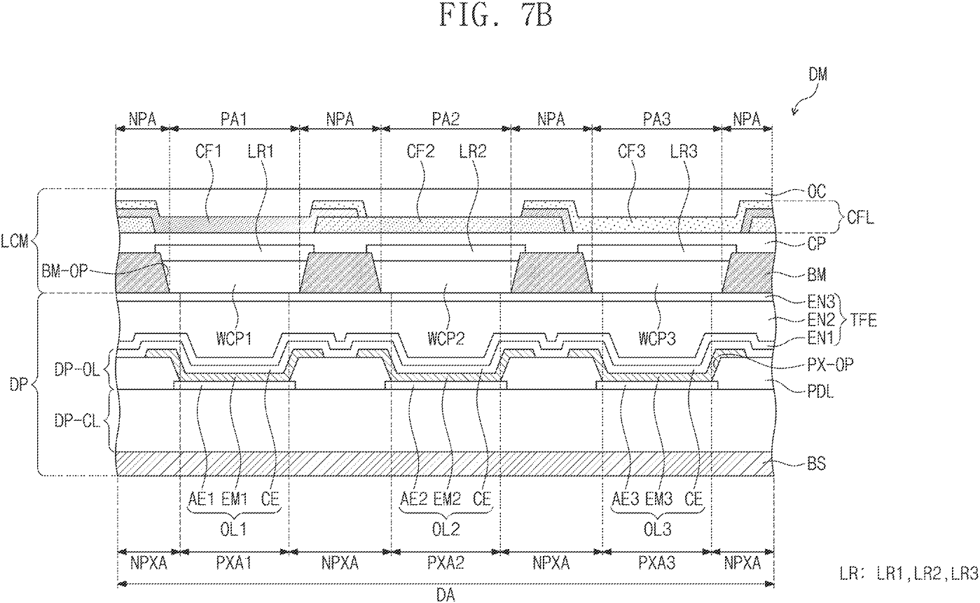

FIGS. 7A and 7B are cross-sectional views of the display module DM according to embodiments. The embodiments of FIGS. 7A and 7B include substantially the same configuration as the above-described display module DM, and there is a difference in some configurations. The following description will be focused on the differences of the embodiments.

Referring to FIG. 7A, the first to third light emitting elements OL1, OL2, and OL3 may have different thicknesses. In an embodiment, the emissive part EM1 of the first light emitting element OL1, the emissive part EM2 of the second light emitting element OL2, and the emissive part EM3 of the third light emitting element OL3 may have different thicknesses.

The luminances, lifetimes, and efficiencies of the first to third light emitting elements OL1, OL2, and OL3 may be adjusted by controlling the thicknesses of the emissive layers and/or the functional layers included in the emissive parts EM1, EM2, and EM3 of the first to third light emitting elements OL1, OL2, and OL3. The thicknesses of the emissive parts EM1, EM2, and EM3 defined to have predetermined luminances, lifetimes, and efficiencies may differ from one another depending on the colors of emitted light. Accordingly, the emissive parts EM1, EM2, and EM3 of the first to third light emitting elements OL1, OL2, and OL3 disposed to correspond to the first to third pixel areas PA1, PA2, and PA3 distinguished from one another based on the colors of emitted light may have different thicknesses.

In an embodiment, the first light emitting element OL1 may be disposed to correspond to the first pixel area PA1 that outputs red light, and the thickness of the emissive part EM1 of the first light emitting element OL1 may be greater than the thicknesses of the emissive parts EM2 and EM3 of the second and third light emitting elements OL2 and OL3. The third light emitting element OL3 may be disposed to correspond to the third pixel area PA3 that outputs blue light, and the thickness of the emissive part EM3 of the third light emitting element OL3 may be less than the thicknesses of the emissive parts EM1 and EM2 of the first and second light emitting elements OL1 and OL2. However, embodiments are not necessarily limited thereto.

The second insulating film EN2 may cover the first to third light emitting elements OL1, OL2, and OL3 having different thicknesses and may provide a flat upper surface. Accordingly, the thickness of the second insulating film EN2 may vary depending on the areas where the second insulating film EN2 is disposed. A portion of the second insulating film EN2 that is disposed on the first light emitting element OL1 and that overlaps the first pixel area PA1 may have a first thickness TH1. A portion of the second insulating film EN2 that is disposed on the second light emitting element OL2 and that overlaps the second pixel area PA2 may have a second thickness TH2. A portion of the second insulating film EN2 that is disposed on the third light emitting element OL3 and that overlaps the third pixel area PA3 may have a third thickness TH3. The first thickness TH1 may be smaller than the second thickness TH2 and the third thickness TH3, and the third thickness TH3 may be greater than the first thickness TH1 and the second thickness TH2.

Referring to FIG. 7B, the low-refractive index layer LR may include a plurality of low-refractive index patterns LR1, LR2, and LR3 spaced apart from each other. That is, the low-refractive index layer LR may be disconnected at locations corresponding to the non-emissive area NPXA (or peripheral area NPA). The plurality of low-refractive index patterns LR1, LR2, and LR3 may include the first to third low-refractive index patterns LR1, LR2, and LR3 disposed on the first to third light control parts WCP1, WCP2, and WCP3, respectively. At least portions of the first to third low-refractive index patterns LR1, LR2, and LR3 may be disposed on the upper surface of the barrier rib BM. A portion of the low-refractive index layer LR may be disposed in the plurality of openings BM-OP. The low-refractive index layer LR (and various patterns thereof) may extend out of the plurality of openings BM-OP and along the barrier rib BM (e.g., along a sidewall which defines a respective opening and along a top surface which is furthest from the encapsulation layer TFE).

Each of the first to third low-refractive index patterns LR1, LR2, and LR3 and the first to third light control parts WCP1, WCP2, and WCP3 has a width in a direction along the encapsulation layer TFE. The first to third low-refractive index patterns LR1, LR2, and LR3 may have widths greater than the widths of the first to third light control parts WCP1, WCP2, and WCP3 disposed to correspond to the first to third low-refractive index patterns LR1, LR2, and LR3, respectively. Accordingly, the first to third low-refractive index patterns LR1, LR2, and LR3 may completely cover the first to third light control parts WCP1, WCP2, and WCP3. As the first to third low-refractive index patterns LR1, LR2, and LR3 have widths greater than the widths of the first to third light control parts WCP1, WCP2, and WCP3, the low-refractive index layer LR may cover all of the first to third light control parts WCP1, WCP2, and WCP3 even though slight misalignment occurs in the process of forming the low-refractive index patterns LR1, LR2, and LR3. Accordingly, the reliability of the display module DM may be improved.

The capping layer CP may be disposed between the low-refractive index layer LR and the color filter layer CFL. The capping layer CP may have a single-layer structure or a multi-layer structure. The capping layer CP having the multi-layer structure may include an inorganic layer and an organic layer. The inorganic layer of the capping layer CP may protect the low-refractive index layer LR and the first to third light control parts WCP1, WCP2, and WCP3 from external moisture. The low-refractive index layer LR and the first to third light control parts WCP1, WCP2, and WCP3 may form a stepped structure including steps. The organic layer of the capping layer CP may cover steps between the barrier rib BM and the low-refractive index patterns LR1, LR2, and LR3 and may provide a flat upper surface for a component to be disposed thereon.

FIG. 8 is a cross-sectional view of a light emitting element OL according to an embodiment. In an embodiment, the light emitting element OL may be a light emitting element OL having a tandem structure that includes a plurality of emissive layers. FIG. 8 schematically illustrates a section of the light emitting element OL provided in the tandem structure.

Referring to FIG. 8, the light emitting element OL may include a first electrode AE, a second electrode CE facing the first electrode AE, and an emissive part EM disposed between the first electrode AE and the second electrode CE. The emissive part EM may include first to fourth stacks ST1, ST2, ST3, and ST4 and first to third charge generation layers CGL1, CGL2, and CGL3.

Each of the first to third charge generation layers CGL1, CGL2, and CGL3 may be disposed between a pair of adjacent stacks. The first charge generation layer CGL1 may be disposed between the first stack ST1 and the second stack ST2, the second charge generation layer CGL2 may be disposed between the second stack ST2 and the third stack ST3, and the third charge generation layer CGL3 may be disposed between the third stack ST3 and the fourth stack ST4. In FIG. 8, the light emitting element OL is illustrated as including the four stacks ST1, ST2, ST3, and ST4. However, the light emitting element OL may include more or fewer stacks than those illustrated in FIG. 8.

Each of the first to fourth stacks ST1, ST2, ST3, and ST4 may include an emissive layer. The first stack ST1 may include a first emissive layer EML-1. The second stack ST2 may include a second emissive layer EML-2. The third stack ST3 may include a third emissive layer EML-3. The fourth stack ST4 may include a fourth emissive layer EML-4. Some of the emissive layers EML-1, EML-2, EML-3, and EML-4 included in the first to fourth stacks ST1, ST2, ST3, and ST4 may emit substantially the same color light, and the other emissive layers may emit different color light. However, without being limited thereto, the emissive layers EML-1, EML-2, EML-3, and EML-4 included in the first to fourth stacks ST1, ST2, ST3, and ST4 may all emit substantially the same color light.

In an embodiment, the first to third emissive layers EML-1, EML-2, and EML-3 of the first to third stacks ST1, ST2, and ST3 may emit substantially the same first color light. For example, the first color light may be blue light. The light emitted by the first to third emissive layers EML-1, EML-2, and EML-3 may have a wavelength range of about 420 nm to about 480 nm. However, without being limited thereto, the first, second, and fourth emissive layers EML-1, EML-2, and EML-4 of the first, second, and fourth stacks ST1, ST2, and ST4 may emit substantially the same blue light. The configurations of the stacks that emit the same color light may be modified in various ways and are not limited to any one configuration.

The first to third emissive layers EML-1, EML-2, and EML-3 of the first to third stacks ST1, ST2, and ST3 may emit the same first color light, and the fourth emissive layer EML-4 of the fourth stack ST4 may emit second color light different from the first color light. For example, the second color light may be green light. The light emitted by the fourth emissive layer EML-4 may have a wavelength range of about 520 nm to about 600 nm. However, without being limited thereto, the third emissive layer EML-3 of the third stack ST3 may emit green light when the first, second, and fourth emissive layers EML-1, EML-2, and EML-4 of the first, second, and fourth stacks ST1, ST2, and ST4 emit substantially the same blue light.

However, in an embodiment, the fourth stack ST4 may be omitted, and the first to third emissive layers EML-1, EML-2, and EML-3 of the first to third stacks ST1, ST2, and ST3 may output substantially the same first color light. For example, the first color light may be blue light.

At least some of the first to fourth emissive layers EML-1, EML-2, EML-3, and EML-4 may have a bi-layer structure including different host materials. For example, one layer of the bi-layer structure may contain a hole transporting host material, and the other layer may contain an electron transporting host material. The electron transporting host material may be a material containing an electron transporting moiety in a molecular structure.

The first stack ST1 may include a hole control layer HTR that transports holes provided from the first electrode AE to the first emissive layer EML-1 and a first intermediate electron control layer METR1 that transports electrons generated from the first charge generation layer CGL1 to the first emissive layer EML-1.

The hole control layer HTR may include a hole injection layer and a hole transporting layer disposed on the first electrode AE. However, without being limited thereto, the hole control layer HTR may further include at least one of a hole buffer layer, a light-emission assisting layer and an electron blocking layer. The hole buffer layer may be a layer that increases light emission efficiency by compensating for the resonance distance depending on the wavelength of light emitted from the emissive layer. The electron blocking layer may be a layer that serves to prevent electron injection from the electron transporting layer to the hole transporting layer.

The first intermediate electron control layer METR1 may include an electron transporting layer disposed on the first emissive layer EML-1. However, without being limited thereto, the first intermediate electron control layer METR1 may further include at least one of an electron buffer layer and a hole blocking layer.

The second stack ST2 may include a first intermediate hole control layer MHTR1 that transports holes generated from the first charge generation layer CGL1 to the second emissive layer EML-2 and a second intermediate electron control layer METR2 that transports electrons provided from the second charge generation layer CGL2 to the second emissive layer EML-2.

The first intermediate hole control layer MHTR1 may include a hole injection layer and a hole transporting layer disposed on the first charge generation layer CGL1. However, without being limited thereto, the first intermediate hole control layer MHTR1 may further include at least one of a hole buffer layer, a light-emission assisting layer and an electron blocking layer.

The second intermediate electron control layer METR2 may include an electron transporting layer disposed on the second emissive layer EML-2. However, without being limited thereto, the second intermediate electron control layer METR2 may further include at least one of an electron buffer layer and a hole blocking layer disposed between the electron transporting layer and the second emissive layer EML-2.

The third stack ST3 may include a second intermediate hole control layer MHTR2 that transports holes generated from the second charge generation layer CGL2 to the third emissive layer EML-3 and a third intermediate electron control layer METR3 that transports electrons provided from the third charge generation layer CGL3 to the third emissive layer EML-3.

The second intermediate hole control layer MHTR2 may include a hole injection layer and a hole transporting layer disposed on the second charge generation layer CGL2. However, without being limited thereto, the second intermediate hole control layer MHTR2 may further include at least one of a hole buffer layer, a light-emission assisting layer and an electron blocking layer.

The third intermediate electron control layer METR3 may include an electron transporting layer disposed on the third emissive layer EML-3. However, without being limited thereto, the third intermediate electron control layer METR3 may further include at least one of an electron buffer layer and a hole blocking layer disposed between the electron transporting layer and the third emissive layer EML-3.

The fourth stack ST4 may include a third intermediate hole control layer MHTR3 that transports holes generated from the third charge generation layer CGL3 to the fourth emissive layer EML-4 and an electron control layer ETR that transports electrons provided from the second electrode CE to the fourth emissive layer EML-4.

The third intermediate hole control layer MHTR3 may include a hole injection layer and a hole transporting layer disposed on the third charge generation layer CGL3. However, without being limited thereto, the third intermediate hole control layer MHTR3 may further include at least one of a hole buffer layer, a light-emission assisting layer and an electron blocking layer.

The electron control layer ETR may include an electron transporting layer and an electron injection layer disposed on the fourth emissive layer EML-4. However, without being limited thereto, the electron control layer ETR may further include at least one of an electron buffer layer and a hole blocking layer.

The first to third charge generation layers CGL1, CGL2, and CGL3 may generate charges (electrons and holes) by forming complexes through an oxidation/reduction reaction when a voltage is applied thereto. The first to third charge generation layers CGL1, CGL2, and CGL3 may provide the generated charges to the stacks disposed adjacent thereto. The first to third charge generation layers CGL1, CGL2, and CGL3 may double the efficiency of currents generated from the adjacent stacks and may serve to adjust the balance of the charges.

Each of the first to third charge generation layers CGL1, CGL2, and CGL3 may include an n-type layer and a p-type layer. The first to third charge generation layers CGL1, CGL2, and CGL3 may have a structure in which the n-type layer and the p-type layer are bonded to each other. However, without being limited thereto, the first to third charge generation layers CGL1, CGL2, and CGL3 may include only one of the n-type layer and the p-type layer. The n-type layer may be a charge generation layer that provides electrons to an adjacent stack. The n-type layer may be a layer in which a base material is doped with an n-dopant. The p-type layer may be a charge generation layer that provides holes to an adjacent stack.

The first to third charge generation layers CGL1, CGL2, and CGL3 may contain a charge generation compound consisting of an aryl amine-based organic compound, metal, metal oxide, carbide, fluoride, or a mixture thereof. For example, the aryl amine-based organic compound may include α-NPD, 2-TNATA, TDATA, MTDATA, sprio-TAD, or sprio-NPB. The metal may include cesium (Cs), molybdenum (Mo), vanadium (V), titanium (Ti), tungsten (W), barium (Ba), or lithium (Li). The metal oxide, the carbide, and the fluoride may include Re₂O₇, MoO₃, V₂O₅, WO₃, TiO₂, Cs₂CO₃, BaF, LiF, or CsF. However, the materials of the first to third charge generation layers CGL1, CGL2, and CGL3 are not limited thereto.

The second electrode CE may be formed to have light transmittance. The second electrode CE may be a transflective electrode or a transmissive electrode. The second electrode CE may contain transparent metal oxide, for example, indium tin oxide (ITO), indium zinc oxide (IZO), zinc oxide (ZnO), or indium tin zinc oxide (ITZO).

When the second electrode CE is a transflective electrode or a reflective electrode, the second electrode CE may contain Ag, Mg, Cu, Al, Pt, Pd, Au, Ni, Nd, Ir, Cr, Li, Ca, LiF/Ca, LiF/Al, Mo, Ti, Yb, W, In, Zn, Sn, or a compound or mixture thereof (e.g., AgMg, AgYb, or MgAg). However, without being limited thereto, the second electrode CE may have a multi-layer structure that includes a reflective film or a transflective film formed of the materials and a transparent conductive film formed of indium tin oxide (ITO), indium zinc oxide (IZO), zinc oxide (ZnO), or indium tin zinc oxide (ITZO).

The second electrode CE may be thinly deposited to have light transmittance. For example, the second electrode CE may have a thickness of 100 angstrom (Å) or less. However, the thickness of the second electrode CE is not limited thereto.

The light emitting element OL may further include a capping layer CPL disposed on the second electrode CE. The capping layer CPL may have a single-layer structure or a multi-layer structure. The capping layer CPL may include an organic layer or an inorganic layer. For example, the inorganic layer of the capping layer CPL may contain at least one of an alkali metal compound such as LiF, an alkaline earth metal compound such as MgF₂, silicon nitride, silicon oxy-nitride and silicon oxide. The organic layer of the capping layer CPL may contain α-NPD, NPB, TPD, m-MTDATA, Alq₃, CuPc, TCTA, an epoxy resin, or an acrylate-based resin. However, the material of the capping layer CPL is not limited thereto.

In an embodiment, the light emitting element OL may emit light in the direction from the first electrode AE to the second electrode CE (e.g., a light emission direction), and based on the direction in which the light is emitted, the hole control layer HTR may be disposed under the plurality of stacks ST1, ST2, ST3, and ST4, and the electron control layer ETR may be disposed over the plurality of stacks ST1, ST2, ST3, and ST4. However, without being limited thereto, the light emitting element OL may have an inverted element structure in which, based on the light emission direction, the electron control layer ETR is disposed under the plurality of stacks ST1, ST2, ST3, and ST4, and the hole control layer HTR is disposed over the plurality of stacks ST1, ST2, ST3, and ST4.

Table 1 below shows the degrees of improvement in the light emission efficiencies of first to third pixel areas PA1 to PA3 in first to third embodiments in which respective encapsulation layers include low-refractive index organic films. The first to third embodiments have the structure of the display module DM illustrated in FIG. 5, and light emitting elements in the first to third embodiments have a tandem structure. In the first to third embodiments, the encapsulation layers include the low-refractive index organic films, and the first to third embodiments differ from one another in terms of the arrangements of emissive parts of the light emitting elements.

The light emitting elements in the first embodiment correspond to the configuration in which the fourth stack ST4 among the components of the light emitting element OL illustrated in FIG. 8 is omitted and the emissive layers EML-1, EML-2, and EML-3 of the first to third stacks ST1, ST2, and ST3 provide blue light. The light emitting elements in the second embodiment correspond to the configuration in which the emissive layers EML-1, EML-2, and EML-4 of the first, second, and fourth stacks ST1, ST2, and ST4 among the components of the light emitting element OL illustrated in FIG. 8 provide blue light and the emissive layer EML-3 of the third stack ST3 provides green light. The light emitting elements in the third embodiment correspond to the configuration in which the emissive layers EML-1, EML-2, and EML-3 of the first, second, and third stacks ST1, ST2, and ST3 among the components of the light emitting element OL illustrated in FIG. 8 provide blue light and the emissive layer EML-4 of the fourth stack ST4 provides green light.

TABLE 1

| Classification | First Pixel Area | Second Pixel Area | Third Pixel Area |
|---|---|---|---|
| First Embodiment | 115% | 114% | 98% |
| Second Embodiment | 111% | 106% | 95% |
| Third Embodiment | 114% | 104% | 98% |

In Table 1, “First Pixel Area” represents the light emission efficiency of the area emitting red light, “Second Pixel Area” represents the light emission efficiency of the area emitting green light, and “Third Pixel Area” represents the light emission efficiency of the area emitting blue light. The light emission efficiencies in Table 1 represent the degrees to which the light emission efficiencies of the pixel areas are improved, compared to the light emission efficiency of a comparative display module according to a comparative example that has a comparative encapsulation layer containing a conventional organic resin having a refractive index of 1.5 or more.

Referring to Table 1, it can be seen that the light emission efficiencies of the first pixel areas and the second pixel areas of the first to third embodiments that emit the red light and the green light are all improved. That is, the low-refractive index organic films of the encapsulation layers may reflect light emitted toward the light emitting elements OL from light control parts WCP1, WCP2, and WCP3 disposed to correspond to the first and second pixel areas, thereby increasing the amount of light converted in the light control parts WCP1, WCP2, and WCP3 and output from the light control parts WCP1, WCP2, and WCP3 and improving the light emission efficiencies of display modules.

Referring to Table 1, the light emission efficiencies of the third pixel areas of the first to third embodiments that emit the blue light may range from about 95% to about 98% and may be substantially similar to, or lower than, the light emission efficiency of the comparative display module according to the comparative example. However, since the degrees to which the light emission efficiencies of the third pixel areas are lowered are smaller than the degrees of improvement in the light emission efficiencies of the first and second pixel areas, the overall light emission efficiencies of the display modules may be improved. That is, the efficiencies of entirely white light emitted from the display modules may be improved by the red light, the green light, and the blue light emitted from the first to third pixel areas.

In a display module DM according to one or more embodiment of the present disclosure, an encapsulation layer TFE disposed between light control parts WCP1, WCP2, and WCP3 and light emitting elements OL may include a low-refractive index organic film (e.g., the second insulating film EN2). As the encapsulation layer TFE includes the low-refractive index organic film, light output from the light control parts WCP1, WCP2, and WCP3 and toward the light emitting elements OL may be reflected back into the light control parts WCP1, WCP2, and WCP3 , and the light emission efficiency of the display module DM may be improved by increasing light re-circulation rates of the light control parts WCP1, WCP2, and WCP3 .

As the encapsulation layer TFE includes the low-refractive index organic film, disposing an additional low-refractive index layer on the encapsulation layer TFE for improvement in the light emission efficiencies of the light control parts WCP1, WCP2, and WCP3 may be omitted, thereby simplifying and reducing processes and costs in manufacturing (or providing) the display module dm. Furthermore, as the encapsulation layer TFE includes the low-refractive index organic film instead of an additional low-refractive index layer being on the encapsulation layer TFE, the thickness of the display module DM may be decreased, thereby reducing an overall thickness of the display module dm. In addition, respective distances between the light emitting elements OL and the light control parts WCP1, WCP2, and WCP3 and along the thickness direction may be decreased, thereby improving the light emission efficiency of the display module dm.

A display module DM according to or more embodiment of the present disclosure may include low-refractive index films disposed over and under light control parts WCP1, WCP2, and WCP3, thereby effectively increasing light re-circulation rates of the light control parts WCP1, WCP2, and WCP3.

As described above, the encapsulation layer TFE disposed under the light control parts WCP1, WCP2, and WCP3 may include the low-refractive index film, and thus the display device DD according to one or more embodiment of the present disclosure may minimize loss of light emitted toward the rear surfaces of the light control parts WCP1, WCP2, and WCP3 and may improve the light emission efficiency of the display device DD.

Furthermore, as the encapsulation layer TFE according to one or more embodiment of the present disclosure includes the low-refractive index film, an additional low-refractive index layer under the light control parts WCP1, WCP2, and WCP3 for prevention of light loss is obviated, and the distance between the source light and the light control parts WCP1, WCP2, and WCP3 as well as the thickness of the display device DD may be decreased.

In addition, the low-refractive index film according to one or more embodiment of the present disclosure may provide a flat upper surface while preventing light loss, thereby improving the reliability of the display device DD.

While the present disclosure has been described with reference to embodiments thereof, it will be apparent to those of ordinary skill in the art that various changes and modifications may be made thereto without departing from the spirit and scope of the present disclosure as set forth in the following claims.

What is claimed is:

1. A display device comprising:
a plurality of light emitting elements which provide source light;
a plurality of light control parts which respectively correspond to the plurality of light emitting elements and have a refractive index, each of the plurality of light control parts receiving the source light and outputting a light having a color; and
an encapsulation layer which is between the plurality of light emitting elements and the plurality of light control parts,
wherein the encapsulation layer includes in order from the plurality of light emitting elements to the plurality of light control parts:
a first inorganic film; and
a low-refractive index organic film which contacts the first inorganic film and has a refractive index lower than the refractive index of the plurality of light control parts.

2. The display device of claim 1, wherein the low-refractive index organic film has a refractive index of about 1.15 to about 1.35.

3. The display device of claim 1, wherein the low-refractive index organic film has a thickness of about 1 micrometer to about 6 micrometers.

4. The display device of claim 1, wherein the encapsulation layer further includes:
a second inorganic film between the low-refractive index organic film and each of the plurality of light control parts, respectively, the second inorganic film having a refractive index, and
the refractive index of the low-refractive index organic film lower than the refractive index of the second inorganic film.

5. The display device of claim 1, further comprising:
a low-refractive index layer facing the encapsulation layer with the plurality of light control parts therebetween, the low-refractive index layer having a refractive index, and
the refractive index of the low-refractive index layer lower than the refractive index of the light control parts.

6. The display device of claim 5, wherein the low-refractive index layer is common to each of the plurality of light control parts.

7. The display device of claim 5, wherein the low-refractive index layer includes a plurality of low-refractive index patterns spaced apart from each other and corresponding to the plurality of light control parts, respectively.

8. The display device of claim 1, wherein
each of the plurality of light emitting elements includes a first electrode, an emissive part and a second electrode in order,
the emissive part includes a plurality of emissive layers, and
the plurality of emissive layers emit light having the same color.

9. The display device of claim 1, wherein
each of the plurality of light emitting elements includes a first electrode, an emissive part and a second electrode in order,
the emissive part includes a plurality of emissive layers, and
the plurality of emissive layers emit light having different colors.

10. The display device of claim 1, further comprising light emission areas which emit light of different colors, wherein
the plurality of light emitting elements include first to third light emitting elements corresponding to the light emission areas,
each of the first to third light emitting elements includes a first electrode, an emissive part and a second electrode in order,
the emissive parts of the first to third light emitting elements have different thicknesses, and
the low-refractive index organic film of the encapsulation layer covers the first to third light emitting elements including the emissive parts having the different thicknesses, and defines a flat upper surface furthest from the first to third light emitting elements.

11. The display device of claim 1, further comprising a plurality of color filters corresponding to the plurality of light control parts, respectively.

12. A display device comprising:
a light emitting element;
a light control part which color-coverts light and corresponds to the light emitting element;
a first low-refractive index film between the light emitting element and the light control part; and
a second low-refractive index film facing the first low-refractive index film with the light control part therebetween, wherein
the first low-refractive index film includes an organic film and has a thickness of about 6 micrometers or less,
each of the light control part, the organic film of the first low-refractive index film and the second low-refractive index film has a refractive index, and
the refractive index of the organic film and the refractive index of the second low-refractive index film are lower than the refractive index of the light control part.

13. The display device of claim 12, wherein the refractive index of the first low-refractive index film is about 1.15 to about 1.35.

14. The display device of claim 12, further comprising:
an inorganic film between the first low-refractive index film and the light emitting element and contacting the first low-refractive index film.

15. The display device of claim 12, further comprising:
an inorganic film between the first low-refractive index film and the light control part and contacting the first low-refractive index film.

16. The display device of claim 12, further comprising in order from the light emitting element, a first inorganic film, the first low-refractive index film and a second inorganic film,
wherein each of the first inorganic film and the second inorganic film contacts the first low-refractive index film.

17. The display device of claim 12, wherein
the light control part is provided in plural including a plurality of light control parts along the first low-refractive index film, and
the second low-refractive index film covers all of the plurality of light control parts.

18. The display device of claim 12, wherein
the light control part is provided in plural including a plurality of light control parts along the first low-refractive index film, and
the second low-refractive index film includes a plurality of low-refractive index patterns which are spaced apart from each other and corresponding to the plurality of light control parts.

19. A display device comprising:
a plurality of light emitting elements;
an encapsulation layer which seals the plurality of light emitting elements, the encapsulation layer including a low-refractive index organic film having a refractive index;
a plurality of barrier ribs on the encapsulation layer, and a plurality of openings defined between the plurality of barrier ribs, the plurality of openings corresponding to the plurality of light emitting elements, respectively; and
a plurality of light control parts in the plurality of openings, respectively, at least one of the light control parts including a quantum dot and having a refractive index,
wherein the refractive index of the low-refractive index organic film is about 1.35 or less and is lower than the refractive index of the at least one of the light control parts.

20. The display device of claim 19, further comprising light emission areas which emit light of different colors, wherein
the plurality of light emitting elements include first to third light emitting elements corresponding to the light emission areas,
the first to third light emitting elements provide a stepped upper surface, and
the low-refractive index organic film covers the stepped upper surface and planarizes the stepped upper surface.
